(19) United States
(12) Patent Application Publication
(10) Pub. No.: US 2025/0036819 A1
(43) Pub. Date: Jan. 30, 2025

(54) DATA INTEGRATION APPARATUS, DATA INTEGRATION METHOD AND PROGRAM, AND DIGITAL CITY CREATION SYSTEM

(71) Applicant: RIKEN, Saitama (JP)

(72) Inventor: Hideyuki O-TANI, Saitama (JP)

(21) Appl. No.: 18/263,590

(22) PCT Filed: Jan. 25, 2022
(86) PCT No.: PCT/JP2022/002713

§ 371 Date: Jan. 31, 2024

(30) Foreign Application Priority Data
Feb. 3, 2021 (JP) 2021-016118

(51) Int. Cl. G06F 30/12; G06F 30/13; G06F 40/56

(52) U.S. Cl. CPC G06F 30/12; G06F 30/13; G06F 40/56

(57) ABSTRACT

A data integration apparatus according to one embodiment includes a controller including a platform for automatically performing a type conversion of an object, an acquisition unit, an interpreter, and an integrator. The acquisition unit acquires each data as a graph in which an object of the platform is a constituent element, or as a collection of information in a language format in which an object is associated with a word. The interpreter performs an interpretation process for converting the constituent element of the graph into a type on a hyponymy-side. The integrator performs an integration process for holding information generated by the interpretation process and information acquired by the acquisition unit, and reflecting the information on the graph. The data integration apparatus operates when the controller repeatedly and automatically performs the interpretation process and the integration process.

### TECHNICAL FIELD

The present invention relates to data integration apparatuses, data integration methods and programs, and digital city creation systems.

### BACKGROUND ART

In order to achieve, at a practical cost, advanced integration of the cyber space assumed by Society 5.0 of the science and technology basic plan, and the physical space, it is indispensable not only to make new attempts with respect to new structures, but to also utilize materials, such as design drawings or the like, which have been voluminously accumulated for old infrastructures. However, because the old materials are basically expressed so as to be visually interpreted by humans, an enormous cost is required for application to a wide-area and high-resolution simulation.

Since the 1980s, extensive study was made to automatically build a three-dimensional model from a design drawing (Non-Patent Document 1). However, because the technology relies on a method of bottom-up assembling of elements (lines and characters) of the drawing, an interpretation failure of a part has a cascade effect to cause a failure of three-dimensionalization, thereby making it difficult to cope with a complex drawing.

In recent years, the mainstream technology captures the drawing into a CAD system and semi-automatically performs a three-dimensionalization. However, utilization of this technology requires an engineer having the knowledge of both the CAD system and the design drawing, and the three-dimensionalization of a large number of structures still requires an enormous cost.

### PRIOR ART DOCUMENTS

### Patent Documents

Patent Document 1: Japanese Laid-Open Patent Publication No. 2011-123644
Patent Document 2: Japanese Laid-Open Patent Publication No. H04-2315142
Patent Document 3: Japanese Laid-Open Patent Publication No. H04-030265
Patent Document 4: Japanese Laid-Open Patent Publication No. H04-275684
Patent Document 5: Japanese Laid-Open Patent Publication No. 2018-109977

### Non-Patent Documents

Non-Patent Document 1: “Automatic Conversion of Mechanical Engineering Drawings to CAD Data”, Journal of the Japan Society of Precision Engineering, Vol. 60, No. 4, pp. 524-529, 1994
Non-Patent Document 2: “A Template-Based Floor Shape Recognition Applied To 3D Building Shapes of GIS Data”, Journal of Japan Society of Civil Engineers Paper Collection A1 (Structural Engineering & Earthquake Engineering), Vol. 70, No. 4 (Journal of Earthquake Engineering Paper Collection, Vol. 33), I_1124-I_1131,
Non-Patent Document 3: “Special Feature, Chapter 2, Image Understanding”, Journal of the Electrical Society, Vol. 105, No. 5, pp. 409-411, 1985
Non-Patent Document 4: “For Image Recognition and Understanding in the Past and in the Future”, Information Processing, Vol. 56, No. 7, pp. 628-633, July 2015
Non-Patent Document 5: “Automatic Combination of the 3D Shapes and the Attributes of Buildings in Different GIS Data”, Journal of Japan Society of Civil Engineers Paper Collection A2 (Applied Mechanics), Vol. 70, No. 2 (Journal of Applied Mechanics, Vol. 17), I_631-I_639, 2014

### DISCLOSURE OF THE INVENTION

### Problem to be Solved by the Invention

Although the technology for automatically building the three-dimensional model by automatically interpreting the design drawing was developed from before, a complete information extraction is difficult and a general-purpose and solid (robust) automatic building of the three-dimensional model has not been reduced to practice. There are demands to provide a general-purpose methodology capable of flexibly and robustly building the three-dimensional model, even with respect to an incomplete automatic interpretation result of the drawing. Further, there are demands for the three-dimensional model to be usable for multi-purpose applications, such as high-resolution numerical simulations, for example.

Data, that is basically expressed for human visual interpretation, and from which a computer cannot extract information when the data is used as is, is referred to as “non-structured data”. For example, 2D-CAD drawings are non-structured data, and are composed of elements such as lines, curves, character strings, or the like, but the meaning of a “drawing” or “table”, which is a collection of elements, is not necessarily explicitly described, and humans visual interpret the “drawing” or “table” to read information therefrom. The non-structured data includes, other than the 2D-CAD drawings, images having pixels as the elements, and point groups having points as the elements. Moreover, in general, data that is not referred to as the non-structured data may be regarded as non-structured data, when the required information cannot be directly extracted from the data. There are demands to provide a technology for fragmentarily reading information by automatically interpreting the meaning of the non-structured data by the computer based on the data of the elements of the non-structured data, and a relationship (including a positional relationship) of the elements.

The drawing or table included in the 2D-CAD drawing expresses fragmentary information of a target (for example, a certain structure) in a physical space to be expressed by the 2D-CAD drawing, and is not the expression target itself (that is, the target in the physical space) of the 2D-CAD drawing, nor a model of the expression target. In this case, the “model” refers to a counterpart in a virtual space of the expression target. Moreover, the “fragmentary information” refers to information, that is not necessarily sufficient to create the model of the expression target, and may be integrated with other information to create the model of the expression target. In order to create the model of the certain target (for example, the structure) at a low cost, the model is required to utilize a plurality of different types of data, from new data to old materials (one type of data), created according to individual purposes, and a technology is required to create the model of the expression target by integrating the fragmentary information distributed among the plurality of data.

In order to sustainably advance the technology for utilizing the data, by coping with a rapid increase in data called data explosion, and an exponential improvement in computer performance continuing for the past several decades, high reusability of a program is required. However, in general, a program that is individually developed reads and writes data having a unique format that is optimized for the individual purpose, and a number of data conversion programs corresponding to the number of combinations of programs are simply required for coordination of the programs. This indicates that a cost of reusability is extremely high, and it is impossible to sustainably advance the technology with a simple approach. This problem is generally solved by an approach that determines a standard expression format, but when the expression format is uniformly and fixedly determined, a data provider and a data user are restricted from independently devising the data format. Further, because all programs depend on a fixed expression format, the technology becomes inflexible.

The present invention provides a loose coupling method that enables simultaneous utilization of both data expressed in a format defined as a standard and data having a unique format optimized for an individual purpose, in order to sustainably advance the technology for the data utilization. In addition, the present invention provides a data interpretation apparatus, method, and program for extracting information from a wide range of data, from new data to old material. Further, the present invention provides a data integration apparatus, method, and program for integrating fragmented information distributed in a plurality of data, to create a model of a data expression target. A digital city platform is also provided.

### Means for Solving the Problem

In the present disclosure, as an example of a means for solving the problem, a method for automatically and robustly interpreting a two-dimensional design drawing, and automatically and flexibly building a three-dimensional model having a different level of detail according to an accuracy of an interpretation result, is presented.

The present application discloses a drawing interpretation method, which not only performs a bottom-up assembling of elements of a drawing, but also automatically identifies a context of the drawing, so as to perform a top-down estimation a matching meaning attached to the drawing, and extract information from the drawing in according to the attached meaning. Specifically, this is implemented by varying (automatic structuring) a graph in which the elements of the drawing are associated with nodes, based on a relationship of constituent elements of the graph.

This method is a robust method in which the graph is not automatically structured, that is, a cascade effect to cause a failure will not occur solely by no improvement of an interpretation accuracy, even if the interpretation fails. In the present study, this automatic structuring method is also adopted in automatic structuring of a three-dimensional model. Hence, it is possible to perform an automatic structuring of the three-dimensional model flexibly having a different level of detail according to the accuracy of interpretation of the drawings. In the three-dimensional model obtained by the automatic structuring method of the present study, information is organized based on the relationship of the constituent elements of the graph, and not only a shape thereof but also a wide variety of information, such as an internal structure, physical properties, or the like of the structure can be held, and use in multi-purpose applications can be expected.

In addition, in the present invention, because an automatic type conversion is performed based on a hypernymy-hyponymy relationship of objects that are the constituent elements of the graph, structuring of an interpreter capable of object-oriented programming is implemented. At the time of interpreting the data and integrating the data, the objects are appropriately converted (downcasted) from the hypernymy-side objects into the more detailed hyponymy-side objects, based on internal data held by the objects and the structure of the graph. The downcasting, which cannot be appropriately performed due to lack of information in a general object-oriented programming, can be performed in the method of the present invention, by supplementing information from the structure of the graph and the data held in a group of objects that are the constituent elements of the graph.

That is, the present invention is configured as follows.

[1] A data integration apparatus comprising a platform configured to automatically perform a type conversion of objects, wherein the platform is provided in a controller of the data integration apparatus, and includes an interpreter and an integrator, and the controller is operated so that the interpreter generates information of a language format in which objects are associated with words, from a graph representing a relationship of the objects of the platform; and the integrator holds the information, and performs creation and conversion of the graph so as to reflect the information on the graph.

[2] The data integration apparatus according to [1], wherein the integrator reflects on the graph, in addition to the information generated by the interpreter, information of the language format input by a user, so as to integrate the information generated by the interpreter and the information of the language format input by the user.

[3] The data integration apparatus according to [1] or [2], wherein the interpreter converts a structure of the graph representing the relationship of the objects of the platform, based on a hypernymy-hyponymy relationship of the objects, so that constituent elements of the graph are converted into a type more on the hyponymy-side.

[4] The data integration apparatus according to any one of [1] to [3], wherein the integrator performs an inference process with respect to the information of the language format held by the integrator, by taking into consideration a hypernymy-hyponymy relationship of the objects, so as to convert the information held by the integrator.

[5] The data integration apparatus according to any one of [1] to [4], wherein the information of the language format is similar to a natural language, and the controller generates an output to a user, according to the natural language or a word or sentence similar to the natural language input by the user.

[6] A data integration method using a platform configured to automatically performing a type conversion of objects, wherein the platform is provided in a controller of a computer, and includes an interpreter and an integrator, and performs a process comprising steps of: generating, by the interpreter, information of a language format in which objects are associated with words, from a graph representing a relationship of the objects of the platform; and holding, by the integrator, the information, to perform creation and conversion of the graph so as to reflect the information on the graph.

[7] A program to be executed by a computer, wherein a platform is provided in a controller of the computer, and includes an interpreter and an integrator, and automatically performs a type conversion of objects, and the program causes the controller of the computer to perform a process comprising steps of: generating, by the interpreter, information of a language format in which objects are associated with words, from a graph representing a relationship of the objects of the platform; and holding, by the integrator, the information, to perform creation and conversion of the graph so as to reflect the information on the graph.

[8] A digital city building system comprising a platform for automatically performing a type conversion of objects, and element programs, wherein the platform implements a loose coupling of the element programs by abstracting an input format of the element programs and extending an application range, by path search and automatic execution of a type conversion based on a hypernymy-hyponymy relationship of the objects.

[9] The digital city building system according to [8], wherein the platform is provided in a controller of the system, and includes an interpreter and an integrator, and the controller is operated so that the interpreter generates information of a language format in which objects are associated with words, from a graph representing a relationship of the objects of the platform; and the integrator holds the information, and performs creation and conversion of the graph so as to reflect the information on the graph.

[10] The digital city building system according to [8] or [9], wherein an expression target of the data integrated by the interpreter and the integrator of the platform is a city or a structure.

### Effects of the Invention

The present invention can implement a data processing platform, which is an interpreter capable of extending the application range of a program by automatically converting an expression format of data based on a meaning of the data, and improving a reusability of the program. The data processing platform can simultaneously utilize both data expressed in a format defined as a standard and data having a unique format optimized for an individual purpose, and sustainably advance the technology for the data utilization.

In addition, it is possible to implement a data interpretation apparatus, a data interpretation method, and a program for extracting information from a wide range of data from new data to old material, using the data processing platform.

Furthermore, it is possible to implement a data integration apparatus, a data integration method, and a program for creating a model of an expression target of data by integrating fragmentary information distributed in a plurality of data, using the data processing platform.

### BRIEF DESCRIPTION OF DRAWINGS

FIG. 1 is a diagram illustrating a physical configuration of a data interpretation apparatus according to a first embodiment.

FIG. 2A is a diagram schematically illustrating conversion of data having expression formats “source 1”, “source 2”, and “source 3” into data having expression formats “target 1”, “target 2”, and “target 3”.

FIG. 2B is a diagram schematically illustrating setting “mediation data” as mediating a conversion from “source 1”, “source 2”, and “source 3” to “target 1”, “target 2”, and “target 3”.

FIG. 3A is a diagram illustrating another state of the mediation data of an automatic data conversion.

FIG. 3B is a diagram illustrating an example of the automatic data conversion in an interpreter of the present invention.

FIG. 4 is an example of a pier structure general map illustrating a pier structure composed of CAD data.

FIG. 5 is a diagram illustrating a “title block” in the pier structure general map.

FIG. 6 is a diagram illustrating an object (class name “LineBuf2D”) composed of lines in the “pier structure general map”.

FIG. 7 is a diagram illustrating that objects not belonging to a subclass “CellSet” are excluded from the object (class name “LineBuf2D”) which is a collection of lines, and six objects are interpreted as “CellSet”.

FIG. 8A is a diagram illustrating that a character string or the like extracted from the CAD data is input with respect to the object of the class “CellSet”, and the object is interpreted as a class “Table”.

FIG. 8B is a diagram illustrating that analysis and classification are performed to determine whether or not an item “title block” is present in the object of the class “Table”, and the object is interpreted as an object of the class “title block” when the item is present.

FIG. 9 is a diagram illustrating that objects not belonging to a subclass “View” are excluded from the object (class name “LineBuf2D”) which is a collection of lines, and eight objects are interpreted as belonging to the class “View”.

FIG. 10 is a diagram illustrating seven cells that remain when cells not belonging to a main structure (D-STR) layer are excluded from the eight objects having the class name View illustrated in FIG. 9.

FIG. 11 is a diagram illustrating that a character string serving as a title, extracted from the CAD data, is input with respect to the object belonging to the class “View”, and an object having an item peculiar to “pier front view” is interpreted as the object having a class name “pier front view”.

FIG. 12A is a diagram illustrating a state where information of a structure is automatically extracted from a front view, a plan view, and a side view.

FIG. 12B is a diagram illustrating a state where a three-dimensional model is automatically created from the information on the structure.

FIG. 13 is a diagram illustrating that “2D front view” included in a 2D-CAD drawing is recognized in steps.

FIG. 14 is a diagram illustrating that “substructure coordinate table” included in the 2D-CAD drawing is recognized in steps.

FIG. 15 is a diagram illustrating that the steps for recognizing the 2D-CAD drawing have a hierarchical structure in the data interpretation apparatus and the data interpretation method according to the present disclosure.

FIG. 16 is a diagram illustrating that, in the present disclosure, two methods of recognizing the 2D-CAD drawing, mainly (1) “information input” and (2) “analysis and interpretation”, are set in the present disclosure.

FIG. 17 is a diagram illustrating a flow of a digital bridge automatic building method.

FIG. 18 is a diagram illustrating an initial graph for drawing interpretation.

FIG. 19 is a diagram illustrating an example of automatic structuring of the graph in the drawing interpretation.

FIG. 20 is a diagram illustrating the automatic building of a digital pier based on a two-dimensional CAD drawing.

FIG. 21 is a diagram illustrating a process of recognizing a title block.

FIG. 22 is a diagram illustrating a physical configuration of the data integration apparatus according to a second embodiment.

FIG. 23A is a diagram illustrating a method of implementing a data processing when developing individually.

FIG. 23B is a diagram illustrating the method of implementing the data processing when utilizing a standard format.

FIG. 23C is a diagram illustrating the method of implementing the data processing when utilizing an automatic conversion.

FIG. 24A is a diagram illustrating a star-shaped network centered on a standard expression format, as an example of a topology of a network formed by an expression format and a conversion path.

FIG. 24B is a diagram illustrating a free network based on the automatic conversion of the expression format, as an example of the topology of the network formed by the expression format and the conversion path.

FIG. 25A is a diagram illustrating a format of a fixed digital city according to the standard format.

FIG. 25B is a diagram illustrating the format of a digital city building system having development sustainability.

FIG. 26 is a diagram illustrating an example of the automatic conversion of the expression format when a monadic function q is L1.

FIG. 27 is an example of a script for interpreting a 2D-CAD drawing “006_P2 pier structure general map.dxf”.

FIG. 28A is a diagram (part 1) illustrating an example of a graph in which a content of each language expression is integrated.

FIG. 28B is a diagram (part 2) illustrating the example of the graph in which the content of each language expression is integrated.

FIG. 29 is a diagram for explaining an example of a process of automatically structuring the graph in which the content of each language expression is integrated.

### MODE OF CARRYING OUT THE INVENTION

Hereinafter, embodiments will be described in detail, with reference to the drawings as appropriate. However, an unnecessarily detailed description may be omitted. For example, a detailed description of what is well known, and a repeated description of configurations that are substantially the same, may be omitted. This is to facilitate the understanding of those skilled in the art, and to avoid the following description from becoming unnecessarily redundant.

The present inventor provides the accompanying drawings and the following description to enable those skilled in the art to sufficiently understand the present disclosure, and does not intend to limit the subject matter described in the claims by the accompanying drawings and the following description.

### 1. Study on Data Processing Platform

First, a data processing platform (DPP) will be described in the sections “1.1. Purpose and Content of Study”, “1.2. Significance and Importance of Automatic Conversion of Data Expression Format”, “1.3. Definition of Logical Equivalence of Data”, “1.4. Requirement and Implementation of DPP”, and “1.5. Conclusions With Respect To Developed Theory and Implementation” (these sections are hereinafter referred to as “disclosure related to present study and devising”). The data processing platform is the subject of the present inventor's study, and functions as an interpreter for building a digital city.

### 1.1. Purpose and Content of Study

### 1.1.1. Need for Digital City

Attempts to quantify damages to a city caused by an earthquake or a tsunami, using a supercomputer, has advanced to interdisciplinary study, such as evaluation of influence on traffic or economy, or the like. A resulting program group is expected to be utilized together with a high-performance computer, and to be useful for comprehensive disaster prevention. However, even in the presence of the computer and the program, application to an actual city is not possible unless there is a digital city where a disaster ca be simulated.

### 1.1.2. Requirements of Digital City

The digital city should enable at least information required to quantify the damage, to be freely extracted therefrom. In addition, while “data explosion” and “exponential improvement of computer performance” occur, the digital city should not be fixed such that it soon becomes obsolete, and should be able to sustainably develop by flexibly coping with new data and new programs.

### 1.1.3. Difficulty of Building Digital City: Heterogeneity

Although building the digital city requires information to be freely extracted from a wide variety of data, and the digital city to sustainably develop, it is not easy to simultaneously achieve both of these goals. Conventionally, in order to freely extract the information, a measure may be taken to standardize and unify an expression format of the data, thereby fixing the expression format. Actually, the data is recorded in an optimum expression format according to a purpose at the time of data creation, and the expression format of existing data is not unified.

### 1.1.4. Building Digital City, Conventional Method and Expected Difficulties

Nevertheless, it is possible to carry out the standardization necessary for the purpose at hand and build the digital city. However, this method is inefficient because it is necessary to develop a digital city and a program for building the digital city starting from an initial stage, every time a change occurs in the purpose, and it is expected that the development of the digital city building technology will reach a limit at a point in time when a complexity of the digital city reaches a stage which cannot withstand a redevelopment.

### 1.1.5. Purpose

Originally, unlike a standardized shape of a machine component, the expression format of the data can be flexibly modified as long as the meaning and content of the data are equivalent, and even a program assuming a specific expression format as an input can be applied to data expressed in different formats if there is a mechanism for automatically modifying the expression format. For example, when a point expressed by another coordinate system, such as a polar coordinate system or the like, is input with respect to a program for computing a distance between two points on a two-dimensional plane expressed by a Cartesian coordinate system, one program can be utilized in common with respect to a plurality of expression formats by automatically converting the coordinate system. If this mechanism can be implemented universally, an information extraction program that does not depend on the expression format can easily be created, and data and programs can easily be replaced.

In the disclosure related to the present study and devising proposes building an interpreter having a mechanism for automatically converting the expression format (referred to as a data processing platform (DPP)), and storing element programs for building a digital city as a library thereof. The term “platform” refers to an entity that functions as a base which aggregates and coordinates the element programs. With respect to the “data processing platform (DPP)” disclosed in the present specification, the term platform means that the DPP functions as a base for aggregating and coordinating element programs.

In a system including the DPP and the library thereof, new data or new programs can be imported by simple addition or replacement of the programs, and the advanced system corresponds to the advanced digital city. Moreover, in order to implement this system in the disclosure related to the present study and devising, the purpose is to provide a method for automatically converting the expression format according to a definition, by defining a logical equivalence of data having different expression formats.

### 1.1.6. Content

The content of the disclosure related to the present study and devising can be summarized as follows. Significance and importance of automatically converting the expression format of the data when building the digital city are emphasized under “1.2.”, and a theory for the conversion, particularly the logical equivalence of the data, are described under “1.3.”. Then, the implementation corresponding to this theory is described under “1.4.”. Conclusions with respect to the developed theory and the implementation is described under “1.5.”.

### 1.2. Significance and Importance of Automatically Converting of Expression Format of Data

1.2.1. Purpose of this Section

In the present section “1.2.”, diversity of the expression formats of data that becomes the material of the digital city, and problems associated with utilization of such expression formats of data caused by the diversity thereof, will be described. It will also be described that, by automatically converting the expression format of the data based on the meaning of the data, the application range of the program, which is usually limited by the expression format of the data, is extended, and the reusability of the program is improved. Further, it will be described that, due to the improved reusability of the program, the system for automatically building the digital city can be implemented as a loosely coupled system in which the element programs can be flexibly added and modified.

### 1.2.2. Diversity of Expression Format of Data and Problem of Utilization

1.2.2.1. Devising with Respect to Expression Format in Each Field

The data serving as the material of the digital city is usually data individually created for some specific purpose, and the expression format thereof is devised according to the purpose and usage.

For example, in general, data is shared in a format determined by a standardization organization, and is often in a text format that can be read by humans, but in high-performance computing, a binary format is usually adopted, and data of the same type is often arranged in a line so that the entire data can be read and written at a high speed. In addition, when retrieving data to be stored for a long period of time, access is usually made to a part of the data, and a data structure based on a group of meaning and content of a retrieval target can be selected. Even with respect to the data having equivalent meaning and content, various expression formats are determined and utilized by a computing entity or a data management entity according to various processing purposes.

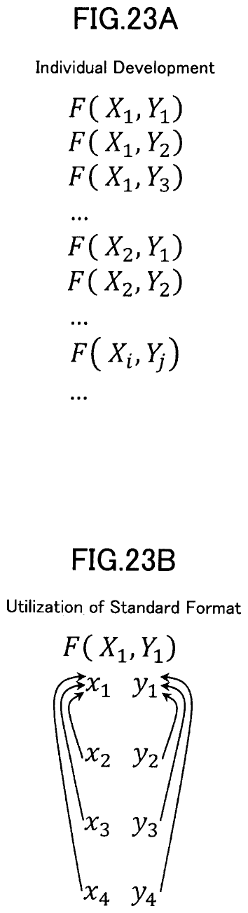

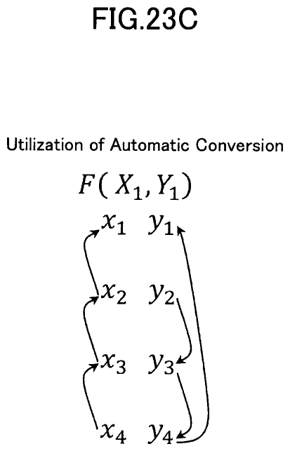

### 1.2.2.2. Difficulty 1 of Building Digital City: Combined Explosion in Program Development (FIG. 23A)

The building and utilization of the digital city can be viewed as a systematic application of processes that input a plurality of data and output target data, each of the processes is characterized by the input data and the output data. In general, even with respect to the processes having the equivalent meaning and content, it is necessary to implement a different program if the expression format of the data is different, and the diversity of the expression format may significantly deteriorate a development efficiency. For example, even with respect to a simple process of outputting a distance between two objects, implementation is required for each combination of expression formats of the input data as illustrated in FIG. 23A, and a combination explosion can easily occur.

FIG. 23A through FIG. 23C are diagrams illustrating three methods of implementing the data processing. An arrow indicates a conversion of the expression format of the data. FIG. 23A illustrates a case of individual development, FIG. 23B illustrates a case of utilizing a standard format, and FIG. 23C illustrates a case of utilizing an automatic conversion. In FIG. 23A through FIG. 23C, F(Xᵢ, Yⱼ) represents a function for performing a predetermined data processing by inputting data xᵢ having an expression format Xᵢ and data yⱼ having an expression format Yⱼ. Further, if i≠i′, the expression formats of Xᵢ and X_{i′} are assumed to be different, and if j≠j′, the expression formats of Yⱼ and Y_{j′} are assumed to be different.

### 1.2.2.3. Difficulty 2 of Building Digital City: Problem of Standard Format

If the expression format to be utilized is unified and the processing program is implemented only with respect to the standard expression format as illustrated in FIG. 23B, it is possible to avoid repeating similar implementations. However, this methodology is not feasible, particularly in the field of high-performance computing, because the methodology prevents the design and utilization of the expression format adapted to the purpose. This is because, in many cases, the program developed in the field of high-performance computing inputs data having an expression format independently designed by a developer for the purpose of improving the computing performance. The usefulness of the standard expression format determined by the standardization organization is evident, but in order to apply a numerical simulation applied with a high-performance program developed in the field of high-performance computing to the digital city, it is necessary to provide a new methodology related to data and program cooperation that can process data having a wide variety of expression formats.

### 1.2.3. Reusing Processing Program by Automatic Data Conversion

### 1.2.3.1. Reusing Processing Program by Automatic Conversion (Including Path Search)

By automatically converting the expression format of the data based on the meaning of the data as illustrated in FIG. 23C, it is possible to extend the application range of the program, and improve the reusability of the program. Usually, the application range of the program depends on the expression format of the data, but when a conversion path that maintains the meaning and content of the data is predefined between the expression formats, and a function of automatically performing a path search that follows this conversion path is implemented, the application range of the program is extended to depend on the meaning and content. In addition, by appropriately defining a path search method, it may be regarded possible to select and execute an optimum one of a plurality of implemented processing programs.

### 1.2.3.2. Relativization of Mediation Data and Standard

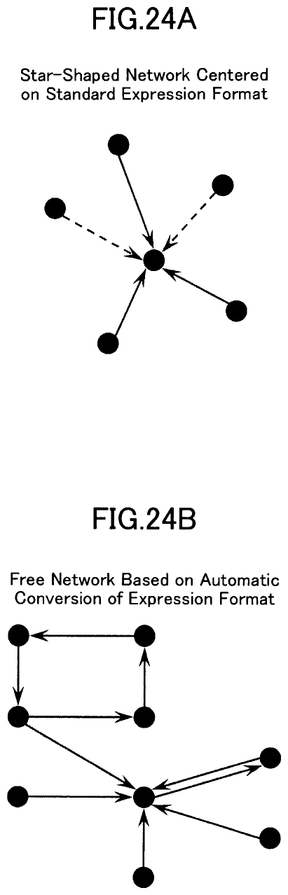

As illustrated in FIG. 24, it is possible to consider a network in which the expression format is a node and the conversion path is a link. FIG. 24 illustrates a topology of a network formed by the expression format and the conversion path. FIG. 24A illustrates a star-shaped network centered on the standard expression format, and FIG. 24B illustrates a free network based on the automatic conversion of the expression format.

The methodology based on the standard expression format limits the topology of the network to the star-shaped network centered on the standard expression as illustrated in FIG. 24A, and the standard expression format serves as a mediation data format for mediating the data and the program. On the other hand, in the methodology based on the automatic conversion of the expression format, a network topology configuration is free, and a coupling position of the data and the program is also free, as illustrated in FIG. 24B. In addition, because the data that is not directly coupled to the program is also indirectly and automatically coupled by the automatic conversion, the data and the program can easily be replaced. Further, this network can grow by adding a new expression format or processing program. As a result of the growth of the network, a star-shaped topology may be formed, but a centrally located expression format is different from the standard expression format defined in a top-down format, and is a de facto standard expression format naturally defined in a bottom-up form.

### 1.2.3.3. Reducing Load of Data User

In recent years, numerous open data, useful as the material of the digital city, have been published and shared through clearing houses. However, because the open data have a wide variety of expression formats, when a developer of the application program combines a plurality of data, it is often necessary to begin by understanding the expression format of each data in order to develop the program for extracting information from the data. If there is a system for implementing a methodology based on the automatic conversion of the expression format, and the information extraction program can be shared, the open data and the already developed processing program can be automatically coupled, to facilitate the development of the application program. In addition, in such a system, because the data can be processed without being conscious of non-essential details of the data, that is, without implementation peculiar to a specific expression format, a load on the data user can also be reduced.

### 1.2.3.4. Improving Reusability by Wrapping of Processing Program

As opposed to the automatic conversion of the expression format concealing details of the data implementation, an application programming interface (API), which is another mechanism for improving the program reusability, conceals details of the program implementation. Providing the city information by a Web API is expected to reduce a development cost of the application program, when sharing the information extraction program. For this reason, because various information of the cities is already provided as Web APIs, and the number thereof is expected to increase in the future, this situation is similar to the increase of the useful data having a unique format. Functions of the application program provided with the API can be characterized by the expression format of the input and output data, and thus, it is possible to apply thereto the automatic conversion of the expression format. In this case, the input data represents an instruction with respect to the API.

### 1.2.4. Digital City Building System

### 1.2.4.1. Definition of Digital City

A working life of a structure that is a constituent element of the city is long, while the progress in research and development is quick. For this reason, it is assumed that data generated in each stage of design, construction, and maintenance is accumulated, and utilized for multiple purposes by applying a technology that is later developed. Actually, a large amount of data is stored with respect to existing structures, and an effective utilization of the stored data is being promoted. For example, a damage estimation of an earthquake or tsunami using numerical simulation is an example of such an effective utilization. In order to perform the numerical simulation, it is necessary to express a model of the city, with a suitable degree of detail, on a computer, and the model is constructed by extracting information of the city from a plurality of data, as fragments, and integrating the fragments into data expressing knowledge with respect to the constituent elements of a real city. In the disclosure related to the present study and devising, the model of the city, as integrated knowledge, is defined as the digital city. The digital city is utilized as an information source for creating target data, such as the input data or the like for the numerical simulation.

### 1.2.4.2. Digital City Based on Standard Format

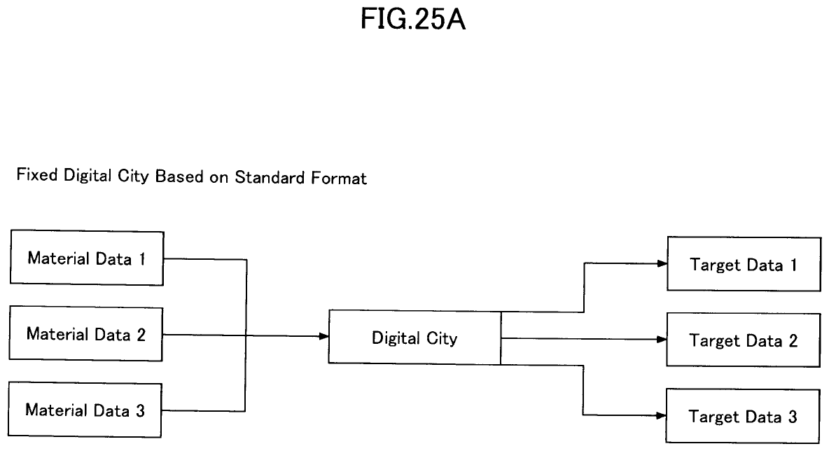

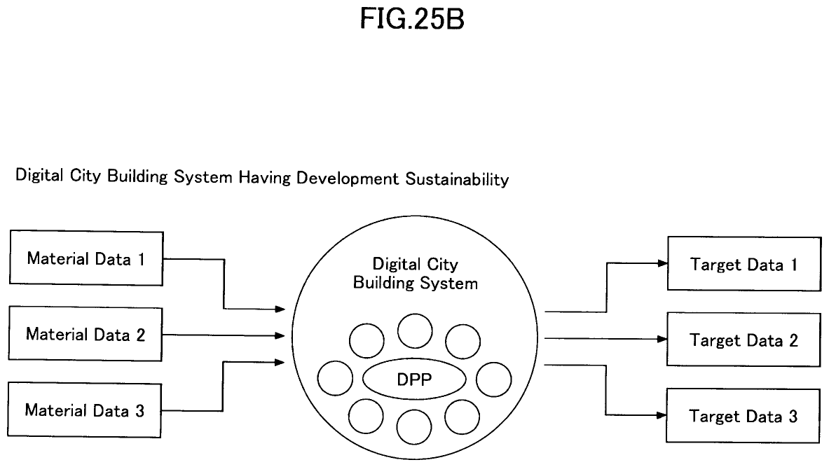

As illustrated in FIG. 25A, a simple form of building and utilizing the digital city is to determine a standard format capable of expressing all the constituent elements of the city, to create data expressed in the determined format from data serving as the material, and to apply a program implemented with respect to the data having the standard format, so to create the target data. However, as described above, the methodology relating to the coordination between the data on which the expression format is based and the program cannot cope with the actual various expression forms. Further, because all programs depend on the standard format, considerable effort is required to modify the standard format. An enormous amount of work is also required to manually convert the data having the existing old standard format according to the new standard format. Consequently, the numerical expression of the city is fixed, and prevents development of the technology.

### 1.2.4.3. Digital City Building System

As illustrated in FIG. 25B, as a form of building and utilizing the digital city in the disclosure related to the present study and devising, the proposed digital city building system is developed for accumulating element programs for building the digital city based on the DPP, which is a uniquely created interpreter having a mechanism for automatically converting the expression format, and storing the element programs for building the digital city. In this system, programs are coupled via the data, and the coupling between the data and the program depends on the meaning and the content of the data, not on the expression format of the data. This means that the coupling can be flexibly modified regardless of the difference in the expression formats, as long as the meaning and the content are the same. It is very important for the development of the digital city building technology to adopt, from an early stage, a design that avoids redundant development and prevents the technology from reaching a limit, by utilizing a loosely coupled system capable of flexibly adding and modifying the element programs.

### 1.3. Definition of Logical Equivalence of Data

When two data expressed in different formats are equivalent to each other, it is possible to correctly replace one data with the other data expressed in a different format, mutually for each of the two data. If there is no clear definition of a condition for enabling each of the two data to be correctly replaced, a meaning and content different from the original meaning and content may be extracted from the replaced data. In the present section “1.3.”, the logical equivalence between the data having different expression formats is defined using predicate logic, so that a logically correct replacement is always possible.

### 1.3.1. Hypernymy-Hyponymy Relationship of Data Expressions

In order to define the logical equivalence between the data expressions, which is a base for automatically converting the data expression format, a predicate logic L1 in which a set of all data expressions is a discussion area D1, is considered. In this case, each data expression format corresponds to a 1-place predicate of L1, and a subset of D1 in which the value of the 1-place predicate is true is the entire data expression expressible by the format. A state where two data expressions are logically equivalent is defined as a state where 2-place predicate ⇒ of L1 representing the hypernymy-hyponymy relationship between the data expressions that are elements of D1 stands bi-directionally. A term “extension” may be used in place of the term “hyponymy”, a term “inclusion” may be used in place of the term “hypernymy”, and a term “extension-inclusion relationship” may be used in place of the term “hypernymy-hyponymy relationship”.

The 2-place predicate ⇒ is defined as satisfying the following reflexivity and transitivity, where → denotes a logical symbol.

∀x(x⇒x)

∀x∀y∀z((x⇒y)&&(y⇒z)→(x⇒z))

Hereinafter, a state where x⇒y stands is referred to as a state where x has y as the hypernymy, or y has x as the hyponymy. In addition, the 2-place predicate ⇔ is defined as follows.

∀x∀y((x⇔y)←→((x⇒y)&&(y⇒x)))

When x⇔y stands, x and y are defined as being equivalent.

A n-place function ø of L1 and a n-place predicate φ are referred to as being regular when the following two conditions are satisfied.

∀x∀y((x⇒y)→(ø( . . . ,x, . . . )⇒ø( . . . ,y, . . . ))) (Formula 1)

∀x∀y(x⇒y)→φ( . . . ,y, . . . )→φ( . . . ,x, . . . ))) (Formula 2)

For example, if x and y are data expressions of a log house and a house, respectively, and Roof (a) is a regular 1-place function that associates a data expression of a roof of “a” with respect to “a”, then (x⇒y)→(Roof(x)⇒Roof(y)) stands from the first formula. This means that “if log house is a house, the roof of the log house is the roof of the house”. In addition, when HasRoof(a) is a regular 1-place predicate representing an attribute “a has a roof”, (x⇒y)→(HasRoof(y)→HasRoof(x)) stands from the second formula. This means that “if the log house is a house, and the house has a roof, then the log house also has a roof”.

An identity function is a regular function, and a predicate that always returns true and a predicate that always returns false are regular predicates. On the other hand, in general, it cannot be determined which function or predicate is a regular function or regular predicate, by merely causing the reflexivity and the transitivity to be satisfied for the hypernymy-hyponymy relationship between the data expressions, much less determine whether or not the two data expressions are in the hypernymy-hyponymy relationship. In the disclosure related to the present study and devising, a state is considered where only basic regular functions and basic regular predicates are first defined, and the regular functions and the regular predicates are successively defined thereafter, and if the formula 1 and the formula 2 are satisfied with respect to arbitrary predefined regular function and regular predicate, the two data expressions are defined as being in the hypernymy-hyponymy relationship. This means that the meaning of the target is assigned by the definition of the regular function and the regular predicate. One purpose of the disclosure related to the present study and devising is to eliminate non-essential differences between the expression formats, and the hypernymy-hyponymy relationship between the data expressions is determined by defining the function and the predicate whose values can be determined regardless of the expression format, as the regular function and the regular predicate.

As an example, an expression format Cartesian2D in which a point on a two-dimensional plane is expressed by the Cartesian coordinate system, and an expression format Polar2D in which a point on a two-dimensional plane is expressed by a polar coordinate system, will be considered. The data expression of Cartesian2D is a set (x, y) of an x-coordinate and a y-coordinate, and the data expression of Polar2D is a set (r, θ) of a radius r and an argument θ. The position of a point on the two-dimensional plane can be measured as an x-coordinate and a y-coordinate with respect to a given Cartesian coordinate system, regardless of data expression. For example, when the Cartesian coordinate system and the polar coordinate system are related to each other as x=r cos θ and y=r sin θ, the x-coordinate and the y-coordinate can be measured from this relation with respect to the data expression (r, θ) of Polar2D. In a case where the measurement of the x-coordinate and the y-coordinate is defined as the regular function for causing the data expression of a real number expression format Real correspond with respect to the point on the two-dimensional plane, and the data expression of Polar2D is a hyponymy of the data expression of Cartesian2D, the measurement results of the x-coordinate and y-coordinate of the two expressions with respect to the two data expressions are equivalent to each other based on the formula 1, that is, the two data expressions represent identical points.

In another example, an expression format Cartesian2D RGB in which a colored point on the two-dimensional plane is expressed by a set of the x-coordinate and the y-coordinate, and a RGB value (x, y, r, g, b). The measurement of the x-coordinate and y-coordinate is also possible with respect to the data expression of Cartesian2D RGB, and in a case where the data expression of Cartesian2D RGB is a hyponymy of the data expression of Cartesian2D, the measurement results of the x-coordinate and y-coordinate of the two expressions with respect to the two data expressions are equivalent to each other, that is, the two data expressions represent identical points, similar to the previous example.

### 1.3.2. Hypernymy-Hyponymy Relationship of Expression Formats

The previous section “1.3.1.” defines the hypernymy-hyponymy relationship between the data expressions. The present section introduces a predicate logic L2 in which a set of all 1-place predicates of L1 is set as a discussion area D2, and the hypernymy-hyponymy relationship is redefined as a relationship of the 1-place predicates of L1. This means that the hypernymy-hyponymy relationship between the data is grasped as a relationship between symbols in which a 1-place predicate name is a label, and each data expression is an instruction target, and enables separate processing of data properties and the data expression method. More particularly, when recording certain information as data, the properties of the data can first be discussed in L2, and a specific expression method of the data can be determined thereafter so that the data has the properties expressed by L2.

1-place predicates A and B of L1 having the hypernymy-hyponymy relationship in L2 are defined as A and B satisfy the following relation in L1.

∀x(A(x)→∃y(B(y)&&(x⇒y)) (Formula 3)

From this formula, it can be immediately seen that the reflexivity and transitivity are satisfied for the hypernymy-hyponymy relationship in L2, similarly as in L1. In addition, considering two special 1-place predicates T and F of L1 satisfying conditions ∀x(T(x)) and ∀x (¬F(x)), respectively, T has all the 1-place predicates as the hyponymy, and F has all the 1-place predicates as the hypernymy.

For each data expression of L1, it is possible to consider a 1-place predicate of L1 whose value is true only for that data expression, and the 1-place predicate in this case is an element of D2. In the disclosure related to the present study and devising, in order to simplify the notations, when the data expression of L1 is denoted by “a”, the element of D2 corresponding to the data expression “a” is also denoted by “a”. However, the data expression is represented in small letters so as to be distinguished from the expression format of the data represented in capital letters. According to the formula 3, when certain data expressions “a” and “b” are in a relationship a⇒b in L1, the relationship a⇒b also stands in L2. In addition, between a certain expression format A and a data expression “a” thereof, a⇒A stands in L2 according to the formula 3.

Under the definition of the formula 3, the regular function and the regular predicate of L1 can be extended to the regular function and the regular predicate of L2 in the following manner, First, a value of a n-place regular function ø in L2 is defined as a 1-place predicate of L1, and a subset of D1 corresponding to this 1-place predicate is defined as a set of all values of the function ø in L1 computed with respect to all original sets of L1 in which each argument of the function ø in L1, that is, the 1-place predicate of L1, is true. Further, a state where the value of the n-place regular predicate q in L2 is true is defined as the state where the value of the predicate q corresponding to L1 is true with respect to an arbitrary original set of L1 in which each argument of the predicate, that is, the 1-place predicate of L1, is true. In this case, formulas 4 and 5 corresponding to the formulas 1 and 2 in L1, also stand in L2 with respect to the regular function and regular predicate in L1 that are extended.

∀A∀B((A⇒B)→(ø( . . . ,A, . . . )⇒ø( . . . ,B, . . . ))) (Formula 4)

∀A∀B((A⇒B)→φ( . . . ,B, . . . )→φ( . . . ,A, . . . ))) (Formula 5)

The relationship between a certain expression format and a data expression thereof corresponds to a relationship between a class and an instance in an object-oriented programming, and the hypernymy-hyponymy relationship corresponds to an inheritance relationship. From this viewpoint, the specialization of the formula 5 into a formula related to the 1-place predicate corresponds to the Liskov substitution principle in the object-oriented programming. However, in the disclosure related to the present study and devising, “class” and “data type” (also simply referred to as “type”) are regarded as synonyms.

When defining an expression format for expressing a truth value as data, it is important that the predicate can be defined as a function. This means that the data can be expressed solely by the regular function, without using the regular predicate. It is also possible to express multi-valued logic, depending on how the truth value is defined. For this reason, the following discussion focuses on the regular function.

When A⇒B in the L2, at least one mapping B<A> from A satisfying

∀x(A(x)→(B(B<A>(x))&(x⇒B<A>(x))))

to B in L1 exists, and this mapping B<A> is referred to as an automatic conversion mapping. When the automatic conversion mapping is implemented, the expression format of data can be automatically converted. The automatic conversion mapping and the element of D2 may be regarded as corresponding to a morphism and an object of the category theory, and the 1-place regular function may be regarded as corresponding to a covariant functor.

### 1.4. Requirement and Implementation of DPP

In the present section “1.4.”, the requirement and implementation of the DPP will be described, and a method in which the DPP automatically converts the expression format of data as required (that is, automatically executes a type conversion), based on the hypernymy-hyponymy relationship between the data defined in the previously described section “1.3. Definition of Logical Equivalence of Data”, and applies the data having the converted expression format to a pre-registered processing program, will be described.

### 1.4.1. Difference in Characteristics Between Data Processing Platform and General Object-Oriented Programming

The following illustrates the difference in characteristics between a data processing platform and a general object-oriented programming.

TABLE 1

| | Data Processing | General Object-Oriented |
|---|---|---|
| | Platform | Programming |
| Definition | Condition required is | Definition is possible even |
| of Inheritance | extension-inclusion | if there is no extension- |
| Relationship | relationship. | inclusion relationship. |
| | Definition is possible | Condition requires sharing |
| | without sharing data | of data structure. |
| | structure. | |
| Data | Between types in | Between types in |
| Abstraction | inheritance relationship, | inheritance relationship, |
| | unique formula (*formula | satisfying Liskov |
| | 4) is always satisfied in | substitution principle |
| | addition to formula | recommended in order to |
| | (*formula 5) obtained by | guarantee substitutability. |
| | expanding Liskov | |
| | substitution principle. | |
| Program | Expanded to format | Specified to expression |
| Application | specified by meaning and | format of input data. |
| Range | content. | |
| Limiting | No limit to number of | Limited to one time. |
| Number of | type conversions. Type | |
| User-Defined | conversion path is | |
| Type | automatically searched, | |
| Conversions | and required number of | |
| | automatic conversions | |
| | are automatically | |
| | performed according to | |
| | search result. | |

As illustrated in Table 1, the DPP according to the present disclosure is based on a concept different from the general object-oriented programming. In the general object-oriented programming, sharing of the data structure is a condition required in defining the inheritance relationship. On the other hand, in the DPP, the sharing of the data structure is not a requirement for the definition of the inheritance relationship. Instead, existence of the hypernymy-hyponymy relationship is the condition required by the inheritance relationship to stand between the classes.

In the DPP, the user can define the inheritance relationship of the classes without being affected by constraints of data structure sharing. The number of automatic (implicit) type conversions is not limited, an optimum path for converting the type is automatically searched, and a required number of conversions is automatically performed along the searched path. In the type conversion of the DPP, in addition to a conversion to a logically equivalent type (referred to as equivalence casting), both a type conversion to a hyponymy side (referred to as downcasting) and a type conversion to a hypernymy side (referred to as upcasting) are automatically performed. However, with respect to the downcasting, a condition that enables the conversion to a conversion destination type is defined for each object, and the downcasting is performed only when the definition is satisfied.

The present inventor described, in C++, the DPP that functions as the interpreter. Of course, those skilled in the art can create a similar interpreter according to the description in the present specification, and the data processing platform of the present disclosure implemented by such an interpreter, as well as the apparatus, method, and program including the platform, are also included in the scope of the present invention.

The description language of the DPP is not limited to C++, and other description languages may be used as long as requirements similar to those described in the present specification are satisfied and similar implementations are possible.

### 1.4.2. Requirement and Implementation

The digital city building system according to the present disclosure related to the present study and devising is configured by accumulating element program groups for building the digital city, based on the interpreter (DPP) of the disclosure of the present invention having a mechanism for automatically converting the expression format, building the digital city from the material data, and creates the target data. In implementing this DPP, the following three points are considered as requirements.

(Requirement 1) Require the DPP to be provided with an interface for instructing the digital city building system to perform a process.

(Requirement 2) Requires the DPP to function as a wrapper of an existing processing program.

(Requirement 3) Requires the DPP to be able to store the processing program as an individually developable library.

As described in the previous section “1.3.”, the relationship between the certain expression format and the data expression thereof corresponds to the relationship between the class and the instance in the object-oriented programming, and the hypernymy-hyponymy relationship corresponds to the inheritance relationship. According to this correspondence, it is assumed that the user of the digital city building system instructs the DPP to perform a process using a kind of object-oriented language. Although details of the implementation will be described later, unlike normal, the language understood by the DPP does not require the data structure sharing between classes having the inheritance relationship, the data structure of the individual classes can be freely designed, and the path search tracing the inheritance relationship and the automatic conversion of the type are performed, as required, when applying a function.

When a developed program is embedded into the DPP, it is inefficient to re-implement the function of the old program in a new language. In the DPP, the class and the function in the C++ language are implemented so as to be wrapped and processed as a class and a function of the DPP. Hence, the DPP can loosely couple the developed data and program according to the methodology of the disclosure related to the present study and devising.

In the DPP, the definition of the class and the processing program related to the class are individually compiled so as to be implemented into a dynamic library. The library is loaded, as required, and the search of the conversion path and the automatic conversion are performed according to the inheritance relationship defined in the library. The user of the DPP can freely extend the system by loading the library of the unique expression format and the processing program.

### 1.4.3. Implementation of Automatic Conversion and Application Method of Processing Program

The expression format can be converted by tracing the automatic conversion mapping, defined between the expression formats, as the conversion path. Various path conversions are possible, but in general, certain data will not necessarily result in equivalent data expressions when converted in different paths. In order for the results of the data conversions to be equivalent regardless of the path, the expression format of the conversion destination should satisfy the following condition in L1.

∀x∀y((A(x)& A(y))→(∃k((k⇒x)&(k⇒y))→(x⇒y))

An expression format satisfying this condition is defined as granular. When performing a conversion to a non-granular expression format, loss of unnecessary information may occur depending on the definition of the automatic conversion mapping. In the case of the material data of the digital city, many of the existing expression formats are granular, but it may be regarded that some expression formats are non-granular. Hence, it is appropriate, in principle, to implement a granular expression format for the class of the DPP, while considering a non-granular expression format with respect to the automatic conversion function of the expression format in the DPP.

The class of the DPP is an object of the predicate logic L2 defined in the previous section “1.3.”, that is, an implementation of the 1-place predicate of L1, and may represent a simple attribute having no internal data, other than the data expression format. In this case, the “attribute” refers to the 1-place predicate of L1, other than the expression format. The automatic conversion mapping from the expression format to the attribute is regarded as an identity mapping. Because the attribute is defined spanning various expression formats, the attribute is generally non-granular. When only the attribute is processed, and the regular function expressing the conceptual properties of attributes are appropriately implemented, it may be regarded that the DPP can also define an ontology description language.

Even if the hypernymy-hyponymy relationship stands between the two expression formats, the automatic conversion of the expression format cannot be performed unless the conversion path coupling the two expression formats is prepared. In order to prevent the user from misunderstanding whether or not automatic conversion is possible, the DPP recognizes that the hypernymy-hyponymy relationship stands only in the case where the automatic conversion mapping is implemented. Although this may at one glance seem contradictory to the theory indicating that the hypernymy-hyponymy relationship is determined by the definition of the regular function and the regular predicate, no inconvenience occurs. Actually, when the program developer clearly distinguishes between the theory-based definition and the implementation-based definition, and recognizes the implementation-based hypernymy-hyponymy relationship only when the theory-based hypernymy-hyponymy relationship stands, it is possible to prevent the implementation-based hypernymy-hyponymy relationship from being erroneously recognized as standing even though the theory-based hypernymy-hyponymy relationship does not stand.

In the network having the expression format as the node and the automatic conversion mapping as the link, the automatic conversion of the expression format is implemented so that the path with a minimum cost is executed. As an example, the automatic conversion of the expression format may search and execute the path with the minimum cost, based on the Dijkstra method, and the cost may be set to 0 in a case where the automatic conversion mapping is the identity mapping, and may be set to 1 in other cases, but the setting is not limited thereto. Further, in order to efficiently search the path, nodes and links not reaching the target are excluded in advance, based on the hypernymy-hyponymy relationship.

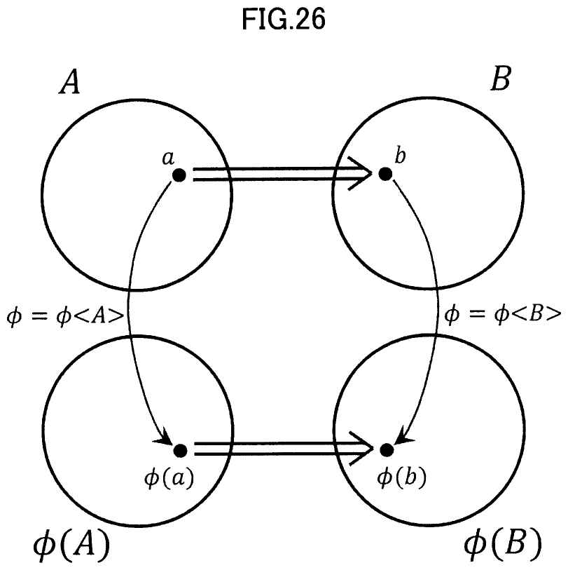

FIG. 26 illustrates an example of the automatic conversion of the expression format based on the formula 4, for a case where the 1-place function of L1 is ø. ø may be implemented in the processing program for each expression format of the input, but when a regular function ø<B> having B as a domain is implemented, an automatic conversion mapping B<A> is defined if A=B in the DPP, and Ø<B> (B<A> (a)) can be computed with respect to an arbitration data expression “a” of A. This may be regarded as an extension of the domain of ø<B> to include A, by the automatic conversion of the expression format. On the other hand, when the function ø<A> is implemented, ø<A>(a)⇒ø<B>(B<A>(a)) from the formula 4. Although ø (a) can be computed in two ways, it is more appropriate to apply the function before dropping the information, as required, than to apply the function after dropping the information by automatic conversion, and thus, DPP adopts the latter computation method when ø<A> is defined. This also applies to the general n-place functions, and the method of selecting the implemented function is the same as polymorphism in the general object-oriented programming.

1.5. Conclusions with Respect to Developed Theory and Implementation

By clearly defining a condition that the two data expressed in different formats are equivalent to each other, and performing the implementation based on the definition, the data expression format can be automatically converted successfully, without causing a logical error. It may be regarded that the digital city building technology can be efficiently and sustainably developed, by accumulating the element programs for building the digital city, based on the DPP.

There are cases where data having the new expression format, extended from the old expression format, can be converted into the old expression format under a specific condition, and the old program can be utilized. From a viewpoint of improving the reusability of the program, a flexible data conversion technology is required in which the possibility of automatic conversion is determined depending on the individual data content. For this reason, the DPP checks whether the data expressed in a certain format satisfies a specific condition, and when the data satisfies the specific condition, the DPP performs the automatic conversion to further extend the application range of the function.

### 2. Purpose of Embodiment

One purpose of the present disclosure according to an embodiment of the present invention is to provide a loose coupling method that enables simultaneous utilization of both data expressed in a format defined as a standard and data having a unique format optimized for an individual purpose, in order to sustainably advance the technology for the data utilization. That is, the purpose of the present disclosure is to provide a method for causing flexible cooperation of different types of data and different types of programs, by achieving loose coupling by abstraction of the data based on the automatic data conversion of the expression format, instead of a standardization for expressing the data in a uniform format.

Another purpose of the present disclosure is to provide a data interpretation method for extracting information from a wide range of data, from new data to old material, using such a loose coupling method.

A further purpose of the present disclosure is to provide a data integration method for creating a model of the expression target of the data, using such a loose coupling method, by integrating the fragmentary information distributed in a plurality of data.

### 3. Platform for Data Processing and Object

In order to achieve the purpose described above, the present inventor devised a platform for the data processing, and an object defined and constructed based on the platform as described under “1. Study on Data Processing Platform”. In the present disclosure, the platform (functioning as an interpreter) devised by the present inventor is referred to as a data processing platform (DPP). In addition, an object defined and constructed based on the DPP is simply referred to as an object. The characteristics of the DPP and the object according to the present inventor will be summarized and described below.

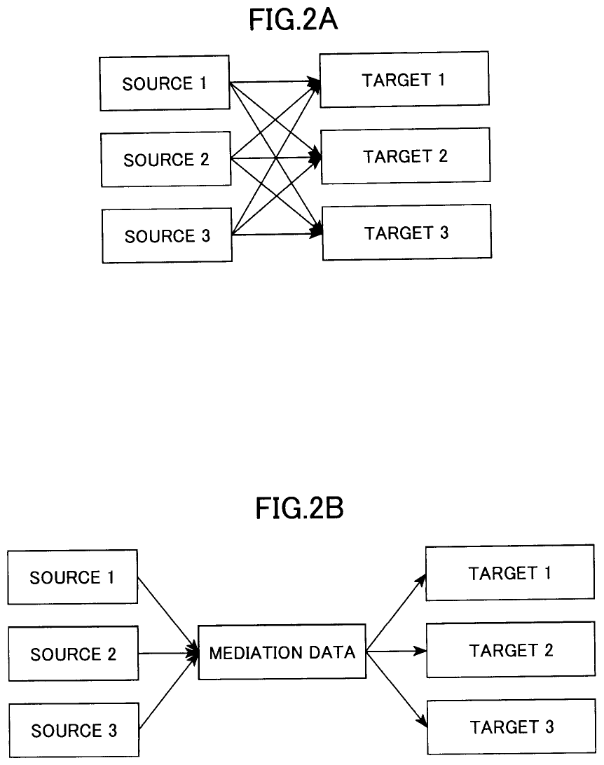

Usually, a unique conversion program is required to convert a certain type of data into another target type of data. For example, as illustrated in FIG. 2A, it is assumed that data having the expression formats “source 1”, “source 2”, “source 3”, . . . , “source M” (that is, the data having M types of expression formats) is converted into data having the expression formats “target 1”, “target 2”, “target 3”, . . . , “target N”. In this case, M×N conversion programs (more particularly, 3×3=9 conversion programs in FIG. 2A) are required.

In this case, as illustrated in FIG. 2B, the setting of “mediation data” is introduced. That is, “mediation data” is set as a mediation for conversion from “source 1”, “source 2”, “source 3”, . . . , “source M” to “target 1”, “target 2”, “target 3”, . . . , “target N”. The number of conversion programs in this case can be M+N (3+3=6 in FIG. 2B). That is, the number of conversion programs decreases from “M×N” to “M+N”.

However, all components (conversion programs and data) of the “mediation data” illustrated in FIG. 2B depend on the “mediation data” illustrated in FIG. 2B, and when a modification occurs in the “mediation data”, which is the standardized data, M+N conversion programs must always be redeveloped.

Therefore, the present inventor of the present disclosure devised the DPP that performs the automatic data conversion as described above.

In the DPP, the object for which the type conversion is automatically performed in an optimum conversion path, is introduced and defined, unlike an object in the general object-oriented programming. The inheritance relationship between the classes of the object is defined by the following (condition 1) through (condition 3).

(Condition 1) The inheritance relationship satisfies the reflexivity and the transitivity.

(Condition 2) The inheritance relationship between the classes is recognized when the hypernymy-hyponymy relationship stands.

For example, a situation is considered where a first object belongs to a first class having (x, y) coordinates, a second object belongs to a second class having (r, θ) coordinates (polar coordinates), and the first class is a subclass of a first superclass. In a case where these classes are specified by C++, there is no inheritance relationship between the first superclass and the second class because of the principle that the inheritance relationship cannot occur unless the coordinate expressions are the same. On the other hand, in a case where these classes are specified by the DPP that defines the object, the inheritance relationship occurs between the first superclass and the second class, because the inheritance relationship stands when the hypernymy-hyponymy relationship stands.

(Condition 3) Polymorphism based on the inheritance relationship between the classes having different internal structures is implemented by performing the automatic path search tracing the conversion process defined between the classes, and the automatic data conversion.

The “hypernymy-hyponymy relationship” described above corresponds to a “is-a relationship” of the object-oriented programming. A case where the hypernymy-hyponymy relationship stands is described above in “1.3. Definition of Logical Equivalence Between Data”.

In the DPP, all of the data are treated as objects.

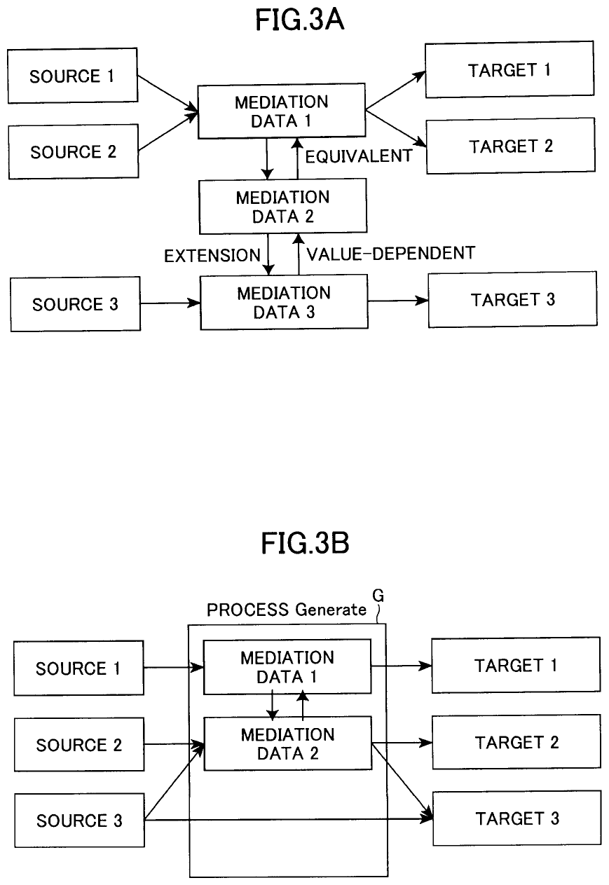

FIG. 3A is a diagram illustrating another state of the mediation data of the automatic data conversion. The data in FIG. 3A, that is, the “source 1”, “source 2”, “source 3”, “mediation data 1”, “mediation data 2”, “mediation data 3”, “target 1”, “target 2”, and “target 3”, are all subjected to objectification. The name of each data is a class name (type name).

In FIG. 3A, it is assumed that “mediation data 1” is set as a mediation for conversion from “source 1” and “source 2” to “target 1” and “target 2”, and that “mediation data 3” is set as a mediation for conversion from “source 3” to “target 3”. Further, it is assumed that the class “mediation data 2” is set between the “mediation data 1” and the “mediation data 3”. In this case, a conversion from “source 1” and “source 2” to “target 3” can be newly implemented via “mediation data 1”, “mediation data 2”, and “mediation data 3”, for example. Similarly, a conversion from “source 3” to “target 1” and “target 2” can be newly implemented via “mediation data 3”, “mediation data 2” and “mediation data 1”.

Here, the relationship between “mediation data 1” and “mediation data 2” is an equivalent relationship, and “mediation data 3” is an extension of “mediation data 2”. In order to modify or extend the mediation data in a state where the old component is usable, two conversions may be considered between the “mediation data 1” and the “mediation data 2”, and two conversions may be considered between the “mediation data 2” and the “mediation data 3”. This means that M+N re-developments are optimized into the development of two conversions.

In the DPP of the present disclosure, each class is defined so that an arrow between the data that are classes (for example, an arrow between the source 1 and the target 1 pointing from the source 1 toward the target 1) indicates the inheritance relationship. In the case of the source 1 and the target 1, “source 1” is a subclass and “target 1” is a superclass, as indicated by the arrows.

Further, the interpreter for the automatic data conversion can also be built in the DPP. FIG. 3B is a diagram illustrating an operation example of the interpreter. First, it is assumed that “mediation data 1” is set as a mediation for the conversion from “source 1” to “target 1”, “mediation data 2” is set as a mediation for conversion from “source 2” and “source 3” to “target 2” and “target 3”, and further, that a mediation for the conversion from “source 3” to “target 3” is not set. Moreover, it is assumed that a mutual conversion is set between the “mediation data 1” and the “mediation data 2”. In this case, the interpreter serves to conceal from the user a complex processing of a portion G enclosed by “Process Generate”.

The interpreter performs the automatic data conversion after internally generating mediation data, as required. For example, the conversion from “source 3” to “target 1” in the case illustrated in FIG. 3B will be considered. In this case, a path “source 3”→“mediation data 2”→“mediation data 1”→“target 1” may be assumed. The interpreter grasps the conversion relationship (that is, inheritance relationship) of each class, and generates the required mediation data, based on the relationship at the time of the actual conversion from the “source 3” to the “target 1”.

Before the actual conversion, the interpreter is configured to assume a plurality of conversion paths, and to compute a cost of the conversion (for example, the number of times the conversion (inheritance) indicated by the arrow is used) with respect to each of the plurality of conversion paths. For example, the conversion from “source 3” to “target 3” in the case illustrated in FIG. 3B will be considered. In this case, it is not impossible to assume a path “source 3”→“mediation data 2”→“target 3” and a path “source 3”→“mediation data 2”→“mediation data 1”→“mediation data 2”→“mediation data 1”→“target 3”, but it is clear that the path “source 3”→“target 3” is the fastest and most efficient path. Thus, the interpreter attempts to automatically determine the conversion path that is most efficient and fastest.

### 3.1. Difference in Characteristics Between DPP and General Object-Oriented Programming

The difference in the characteristics between the DPP and the general object-oriented programming is as illustrated in the table described above.

Next, “different expression formats” will be described. A “text format” and a “binary format” are examples of different expression formats.

Further, for example, there are countless expression formats, such as png, jpeg, bmp, and tif in the case of image data, and avi, mpeg, mov, and wmv in the case of dynamic image data, and the expression formats are different if the image data or the dynamic image data are different.

In addition, even in a case of a text format, there is a difference in:
the expression format having a newline code that is LF,
the expression format having the newline code that is CR+LF,
the expression format having the newline code that is CR, or the like,
   depending on the difference in the newline code.

In terms of the class of the C++ language, the following classes A and B have different expression formats because the data storage orders are different.
class A {double x; double y;};
class B {double y; double x;};

A programming language is also one of the expression formats for expressing instructions to the computer, and different programming languages, such as C++, C, fortran, python, or the like, have different expression formats.

Even if it is determined that the gender is to be written as M or F, or as male or female, this corresponds to determining the expression format (that is, different expression formats).

3.2. Graph in which Objects are Associated with Nodes

In the present disclosure, the data interpretation and the data integration are performed by constructing a graph in which the objects are associated with the nodes. The graph generally includes the nodes, which are constituent elements of the graph, and the links linking between two nodes. In the graph of the present disclosure, only one object is associated with each node and each link, and each link has an orientation. Each link of the graph of the present disclosure corresponds to the 2-place relationship defined by the predicate logic L2 of the data processing platform, and the orientation of each link distinguishes the nodes at both ends of the link. In the present disclosure, when a downcasting of an object associated with a constituent element of a certain graph occurs, an automatic structuring according to a new object after the downcasting may occur. That is, the downcasting of the object associated with each constituent element of the graph provides a starting point for automatically interpreting and integrating the data.

### 4. [First Embodiment]

Next, a data interpretation method and a data interpretation apparatus according to a first embodiment will be described.

### 4.1. Configuration of Data Interpretation Apparatus

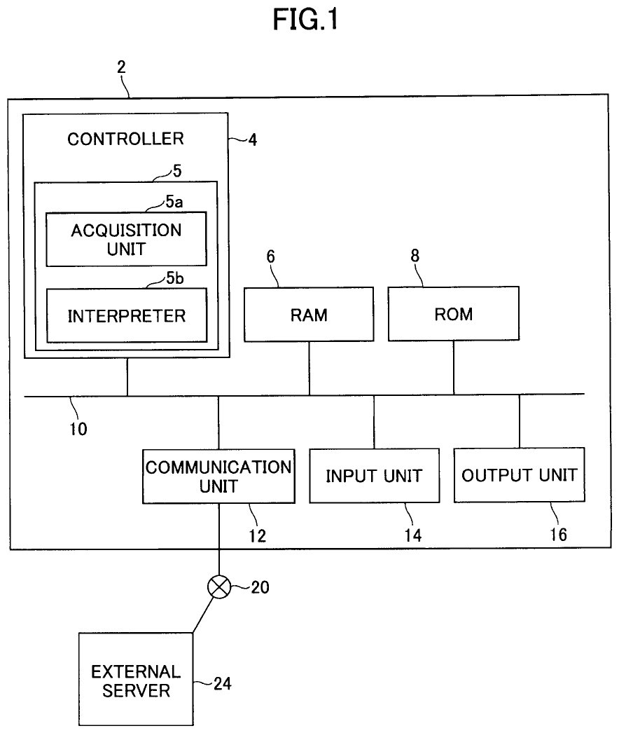

FIG. 1 is a diagram illustrating a physical configuration of a data interpretation apparatus 2 according to the present embodiment. The data interpretation apparatus 2 includes a controller 4 corresponding to a hardware processor, a random access memory (RAM) 6 corresponding to a memory, a read only memory (ROM) 8 corresponding to a memory, a communication unit 12, an input unit 14, and an output unit 16. These components are connected to each other via a bus 10, so that data transmission and reception are possible among these components via the bus 10.

The controller 4 performs a control related to execution of a program stored in the RAM 6 or the ROM 8, and performs computation and processing of the data. The controller 4 is a processor that executes various programs (for example, a program for data interpretation). The controller 4 receives various input data from the input unit 14 and the communication unit 12, displays a computation result of the input on the display unit 16, stores the computation result in the RAM 6 or the ROM 8, and transfers the computation result to an external server through the communication unit 12. The controller 4 is configured by a central processing unit (CPU) or the like.

The RAM 6 is a data rewritable storage unit, and is configured by a semiconductor storage element, for example. The RAM 6 stores programs, such as applications or the like to be executed by the controller 4, and data.

The ROM 8 is a data read-only storage unit, and is configured by a semiconductor storage element, for example. The ROM 8 stores programs, such as firmware or the like, and data, for example.

The communication unit 12 is a communication interface that connects the data interpretation apparatus 2 to an external network 20.

The input unit 14 receives the data input from the user, and includes, a keyboard, a mouse, a touch panel, and a scanner, for example. For example, when reading non-structured information, such as the 2D-CAD drawing, as the input data, image information (raster data) can be acquired using the scanner.

The output unit 16 visually displays the computation result of the controller 4, and is configured by a liquid crystal display (LCD), for example.

The program may be provided by being stored in a computer-readable storage medium, such as the RAM 6, the ROM 8, or the like, or may be provided from an external server 24 via the external network 20 to which the communication unit 12 connects. It is preferable that the CAD data, and the object based on the CAD data are provided from the external server 24 or the like via the external network 20 to which the communication unit 12 connects. In the data interpretation apparatus 2, the controller 4 executes a program for the data interpretation, thereby implementing various functions of an acquisition unit 5a, an interpreter 5b, or the like. These physical configurations are merely examples, and may not necessarily be configurations that are independent. For example, the data interpretation apparatus 2 may include a large scale integration (LSI) or a very LSI in which the CPU, the RAM 6, and the ROM 8 are integrated.

The controller 4 is provided with a platform 5 (data processing platform in this example). The platform 5 includes functional blocks, including the acquisition unit 5a and the interpreter 5b.

The acquisition unit 5a acquires the input data as an object. The input data may be structured data, or may be non-structured data.

The interpreter 5b creates an initial graph with respect to the object acquired by the acquisition unit 5a. Further, the interpreter 5b interprets a result of automatically structuring a graph from the initial graph, as an interpretation of the input data. In this interpretation, the interpreter 5b appropriately performs the type conversion of the object associated with each node and each link of the graph, to the hyponymy-side or the hypernymy-side.

### 4.2. Operation of Data Interpretation Apparatus

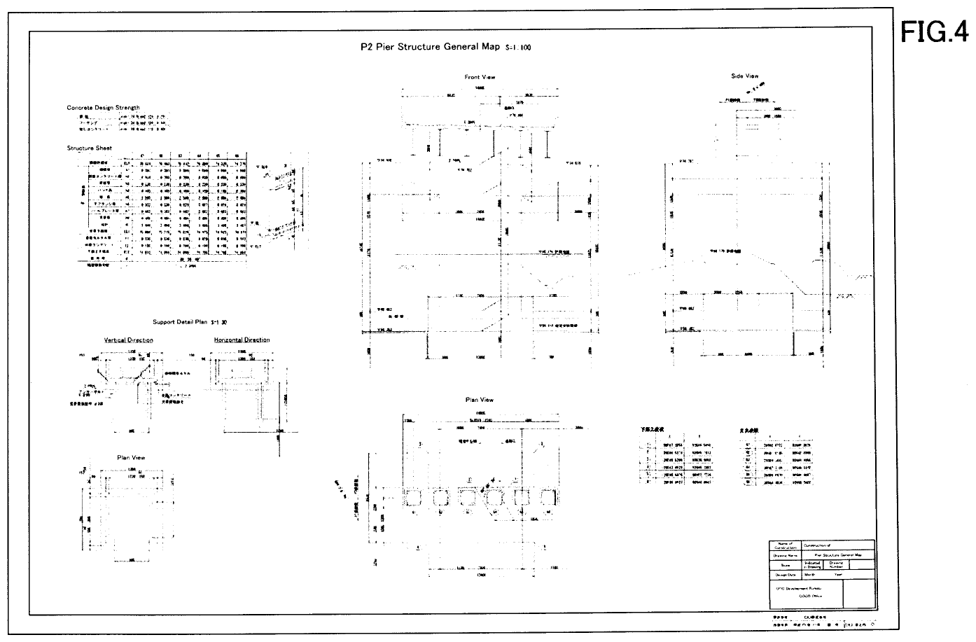

FIG. 4 is an example of a pier structure general map illustrating a pier structure composed of CAD data. Data of the pier structure general map, that are CAD data, include line segments, curves, character strings, or the like as constituent elements, and a collection of constituent elements can be interpreted as a “drawing”, such as a plan view, a front view, or the like, and a “table”, such as various tables or the like.

### 4.2.1. Process of Interpreting Data

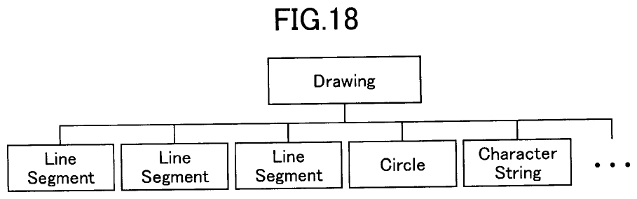

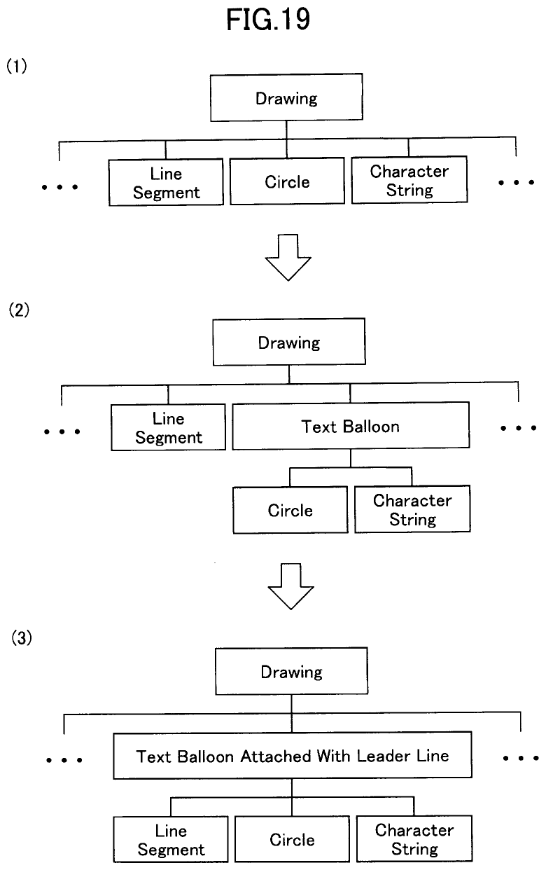

The process of generating a graph in which objects representing elements of the drawing are associated with the nodes, using a design drawing object as an input, regards the generated graph as an interpretation result of the drawing. As illustrated in FIG. 18, a graph in which all elements, such as the line segments, the character strings, circles, or the like included in the drawing are arranged in the same hierarchal level, is set as the initial graph, and the graph is successively and automatically structured. However, in a case where an element in the drawing data is structured from the beginning, a graph reflecting the structure may be regarded as the initial graph. As an example, FIG. 19 illustrates a process of recognizing a text balloon with leader lines, as an example of the automatic structuring of the graph. In FIG. 19, in a case where a circle includes a character string in the drawing (upper row), the two are collectively interpreted as a text balloon (middle row), and further, in a case where a broken line is connected to the balloon, the broken line is regarded as the leader line (lower row). That is, the text balloon is recognized from the inclusion relationship between the circle element and the character string element, and the leader line is recognized from the connection between the text balloon and the line segment element. The relationship between the constituent elements of the graph represents a context that specifies how the elements of the drawing are used, so that a role of “leader line” is assigned to the line segment element that becomes a portion of the text balloon with leader lines.

### 4.2.2. Operation of Interpreting “Title Block” in Table

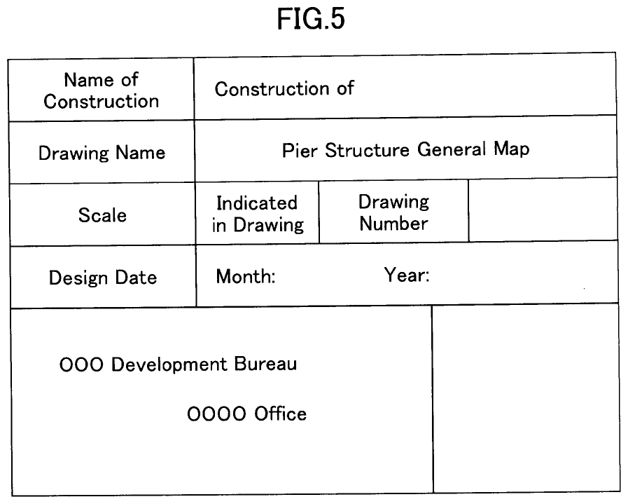

In the pier structure general map illustrated in FIG. 4, a procedure for interpreting the “title block” illustrated in FIG. 5 will be described. The CAD drawing standard (Ministry of Land, Infrastructure, Transport and Tourism) specifies the “title block” to be described in the lower right corner of the pier structure general map. In the example of the pier structure general map illustrated in FIG. 4, the title block is also provided at the lower right corner. Further, the “title block” is composed of lines and character strings in the CAD data.

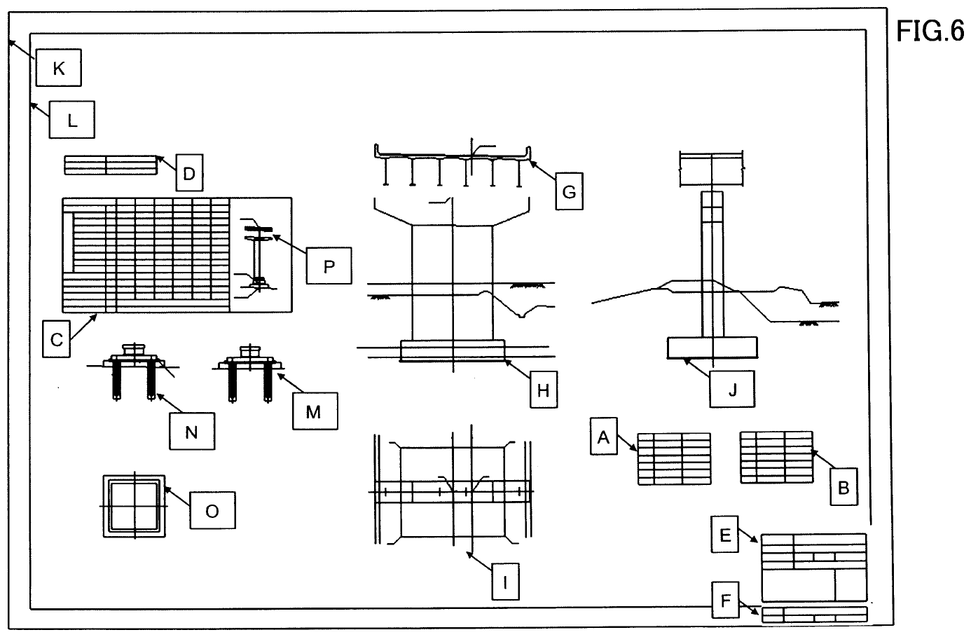

First, in the CAD data “pier structure general map”, the data which is a collection of lines is formed into an object (with a class name “LineBuf2D”, for example). FIG. 6 is a diagram illustrating the object (class name “LineBuf2D”) composed of lines in the “pier structure general diagram”. Sixteen objects, from “A” through “P”, are illustrated.

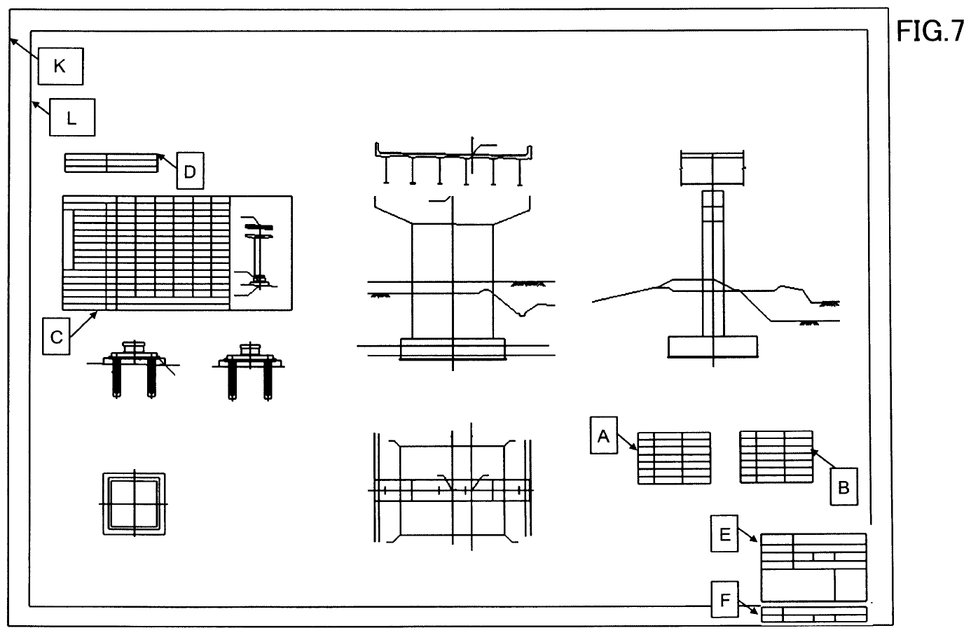

Next, as illustrated in FIG. 6, an object (class name “LineBuf2D”), which is a collection of lines and cannot be interpreted as a set of cells, is excluded from candidates of the “title block”. In this case, a class “CellSet” is defined for the set of cells, and thus, a downcasting from the object (class name “LineBuf2D”), which is a collection of lines, to a subclass “CellSet”, is automatically performed. FIG. 7 is a diagram illustrating that the object (class name “LineBuf2D”), which is a collection of lines, is downcast to the subclass “CellSet”, and the candidates of the “title block” are the remaining eight objects. Objects “A”, “B”, “C”, “D”, “E”, “F”, “K”, and “L” are the candidates of the “title block”.

In order to exclude an object that cannot be interpreted as a set of cells, from the object (class name “LineBuf2D”) which is a collection of lines, a function for downcasting from the class “LineBuf2D” is predefined with respect to the subclass “CellSet”. In this case, the function predefined for downcasting from the superclass to the subclass is referred to as an input function. When the downcasting of an object fails, this object excluded from the candidates of the “title block”. The inheritance relationship between the subclass “CellSet” and the class “LineBuf2D” is based on the hypernymy-hyponymy relationship indicating that if interpreted as the set of cells “CellSet”, it must also be interpreted as the set of lines “LineBuf2D” (refer to (Condition 2) above).

Furthermore, when excluding the object that cannot be interpreted as a set of cells, from the object (class name “LineBuf2D”) which is a collection of lines, a value indicating a probability of downcasting from the superclass to the subclass (for example, a value indicating a percentage of the probability that the object interpreted as the set of cells is actually a set of cells), that is, a likelihood, can be added to the object at the time of conversion to the subclass (at the time of executing the input function). When computing the likelihood, it is also possible to refer to a likelihood added to the superclass.

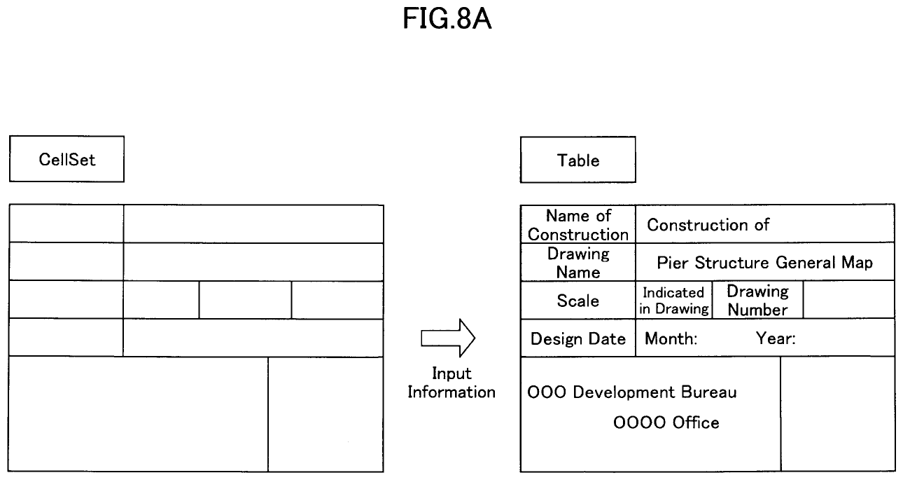

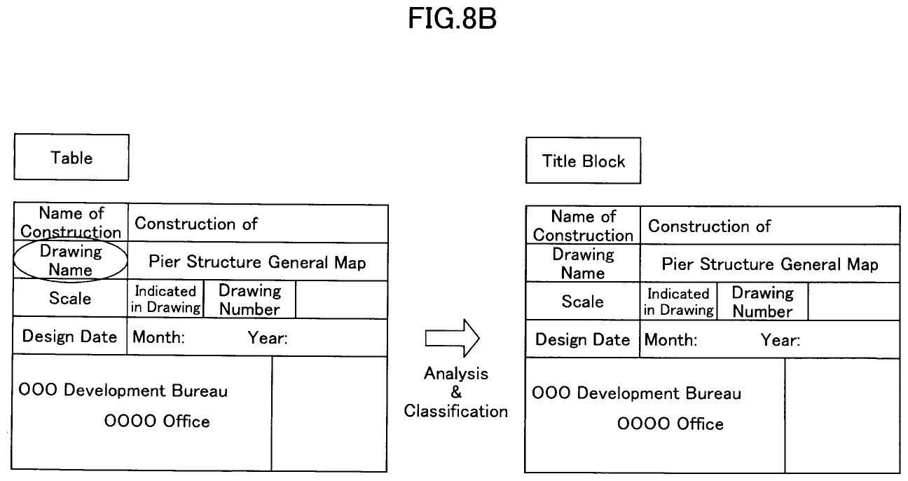

Next, as illustrated in FIG. 8A, an attempt is made to downcast the object of the class “CellSet” to the subclass “Table”. With respect to the input function in this case, CAD data elements (lines, character strings, or the like) are input together with the object of the superclass “CellSet”, and elements included in each cell of the set of cells are extracted. In a case where a certain number of character strings or the like are input with respect to the object of the class “CellSet”, the input function can be defined so that the downcast succeeds, and the object downcast to the class “Table” is interpreted as “Table”.

Next, as illustrated in FIG. 8B, a check is made to determine whether or not a predetermined item, that is, an item “drawing name” in this example, exists in the object of the class “Table”. If the predetermined item exists, the object is downcast to the object of the class “title block”, and interpreted as the “title block”. In this state, the downcasting is performed not based on the input function, but based on a function (referred to as an is function) which is predefined for the class and determines whether or not the downcasting is possible from internal data of the class, and a function (referred to as a cast function) which performs the actual downcasting. In this case, the downcasting by the is function and the cast function will be referred to as downcasting by analysis and classification. The “title block” is interpreted in the manner described above.

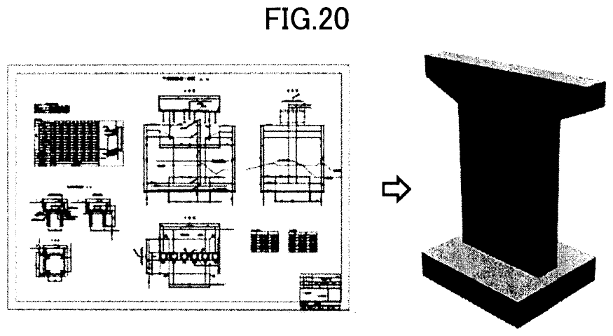

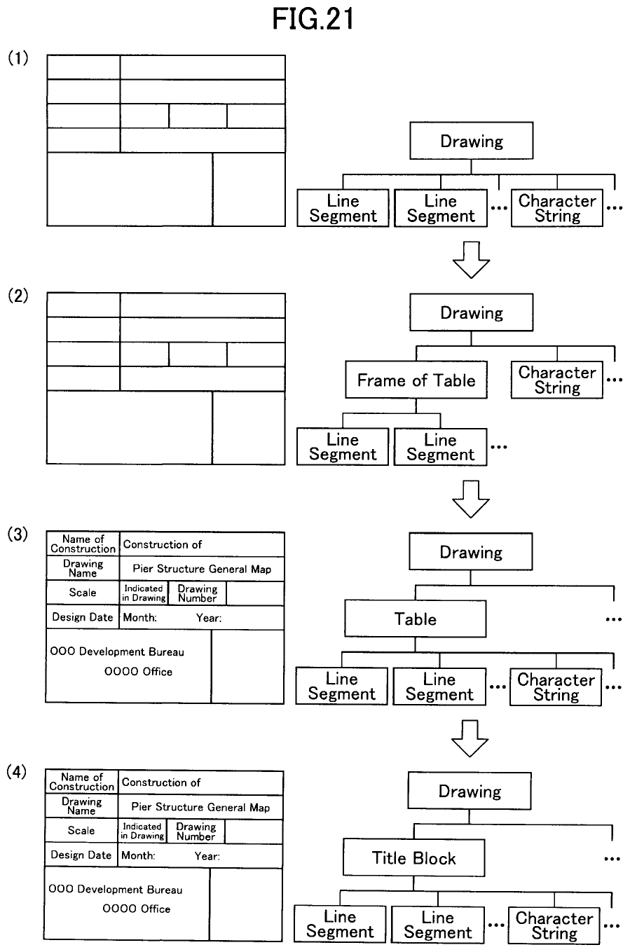

In this example, an operation of interpreting the “title block”, which is a table, will simply be described from a viewpoint of automatically structuring the graph. FIG. 21 illustrates a process of recognizing the “title block” defined in the CAD drawing standard (Ministry of Land, Infrastructure, Transport and Tourism). In order to recognize the “title block”, a collection of connected line segments is first extracted as illustrated in FIG. 21(1), to determine whether or not a “frame of table” is exists, from an arranged state of the extracted line segments. In a case where the “frame of table” is determined to exist as illustrated in FIG. 21(2), information of each cell of the table is recorded in the object expressing the frame of table. Using this cell information, a check is made from the drawing whether or not a character string is arranged in the cell, and in a case where the character string is arranged in the cell, a “table” is determined (FIG. 21(3)), and the character string is stored as cell information. In a case where a condition, such as “construction name” exists or the like, as an item of the cell, is satisfied with respect to the table of the drawing according to the CAD drawing standard, the “table” can be recognized as the “title block” as illustrated in FIG. 21(4).

### 4.2.3. Operation of Interpreting Drawing “Pier Front View”

Next, in the pier structure general map illustrated in FIG. 4, a procedure for interpreting a drawing “pier front view” will be described. In FIG. 4, the “pier front view” is provided at an upper center.

First, in the CAD data “pier structure general map”, the data which is a collection of lines is formed into an object (class name “LineBuf2D”). FIG. 6 is a diagram illustrating the object composed of lines in the “pier structure general diagram”. Sixteen objects, from “A” through “P”, are illustrated.

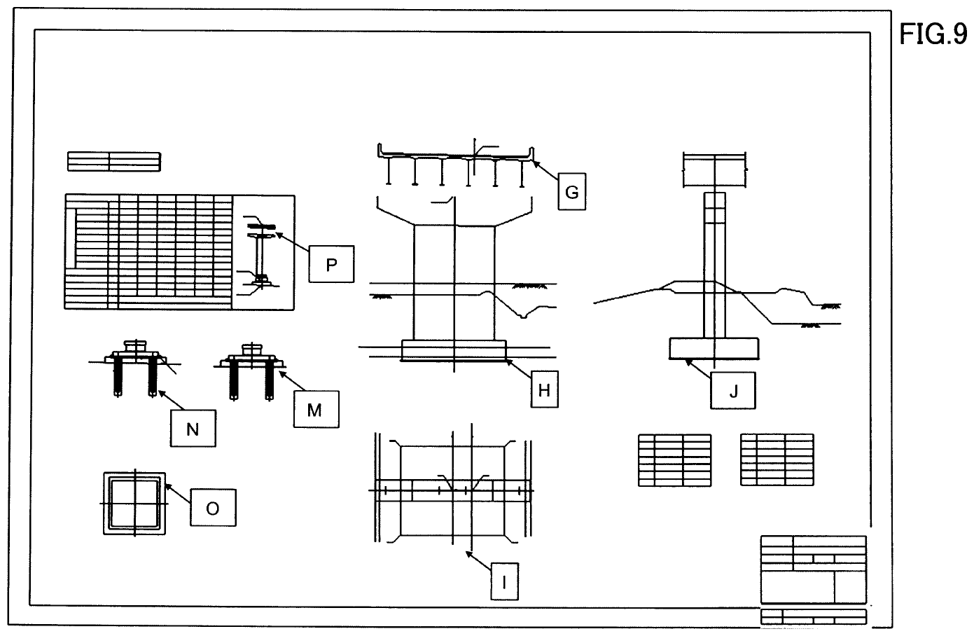

Next, when excluding an object which cannot be interpreted as a drawing “View” with dimensional values, from the object (class name “LineBuf2D”) which is a collection of lines, a function for downcasting from the class “LineBuf2D” is predefined with respect to a subclass “View”. When the downcasting of the object fails, this object is excluded from candidates interpreted as “View”. The inheritance relationship between the subclass “View” and the class “LineBuf2D” is based on the hypernymy-hyponymy relationship indicating that if interpreted as the drawing “View” with dimensional values, it must also be interpreted as a collection of lines “LineBuf2D” (refer to (Condition 2) above). FIG. 9 is a diagram illustrating that objects not belonging to the subclass “View” are excluded from the object (class name “LineBuf2D”) which is a collection of lines, and eight cells remain. Cells “G”, “H”, “I”, “J”, “M”, “N”, “O”, and “P” remain.

When downcasting from the object (class name “LineBuf2D”) which is a collection of lines to the drawing “View” with dimensional values, a value indicating the probability of downcasting from a superclass to a subclass (for example, a value indicating a percentage of the probability that the object interpreted as a drawing with dimensional values is actually a drawing with dimensional values), that is, a likelihood, can be added to the object at the time of conversion to the subclass.

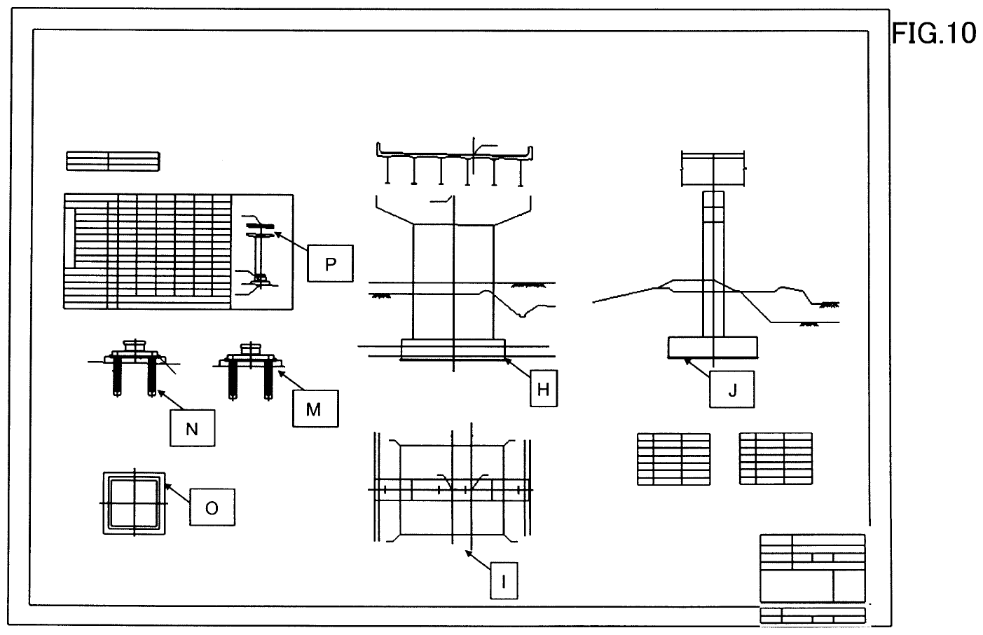

In order to check whether or not the object is the “pier front view”, a reference is made to a predetermined item of the internal data of the object, that is, a layer in this example, and the layer is analyzed and classified to determine whether or not there exists a child element of the object belonging to a main structure (D-STR) layer. If all elements of the object do not belong to the main structure (D-STR) layer, the object is excluded from the candidates of the “pier front view”. In FIG. 10, among the eight objects having the class name View illustrated in FIG. 9, the object not belonging to the main structure (D-STR) layer is excluded, and the seven objects illustrated are added with “H”, “I”, “J”, “M”, “N”, “O”, and “P”.

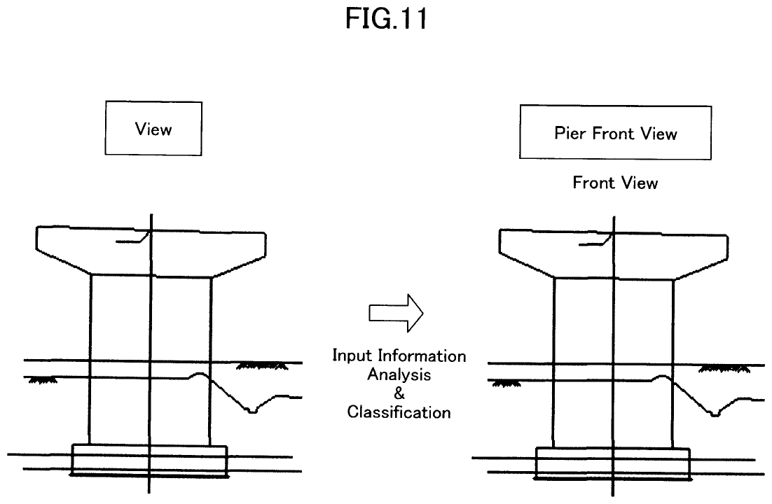

In the downcasting using the input function (referred to as a downcasting by inputting information), it is possible to determine whether or not a downcasting is possible using additional information in addition to the unique internal data of each object. As illustrated in FIG. 11, a character string that becomes the title is input from the CAD data, with respect to the object having the class “View”, and is interpreted as “pier front view”. The “pier front view”, which is a drawing, is interpreted in the manner described above.

### 4.2.4. Summary of Operations of Interpreting Drawing

In the data interpretation apparatus and the data interpretation method according to the present embodiment, the meaning and content of the 2D-CAD drawing are recognized step by step.

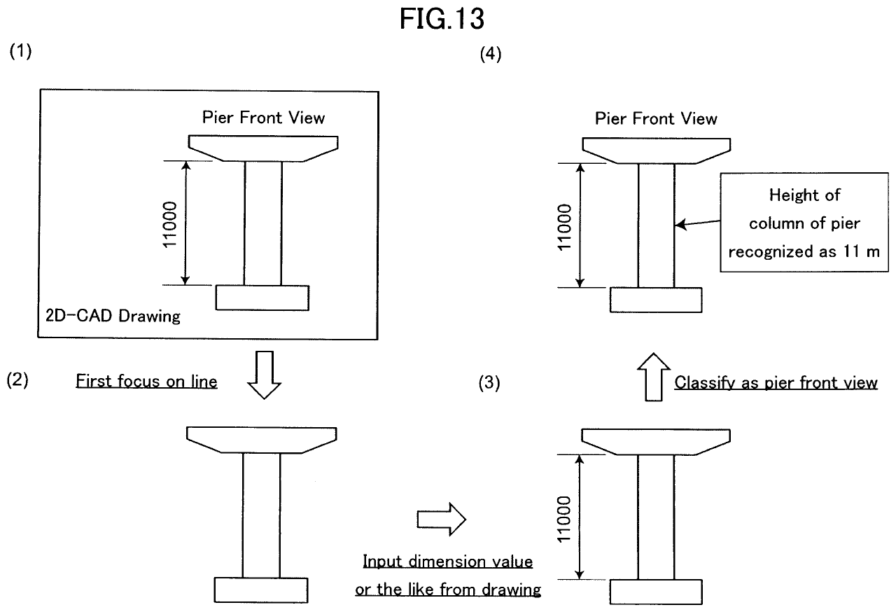

With respect to the various drawings, such as the front view, the plan view, or the like, attention is drawn to the lines, as illustrated in FIG. 13(1) and FIG. 13(2). In other words, objectization (class name “LineBuf2D”) is performed with respect to the data, which is a collection of lines. Next, as illustrated in FIG. 13(2), FIG. 13(3), and FIG. 13(4), the dimensional values or the like are input from the drawing, and then the object is interpreted as an object having the class name “View”, and further interpreted as an object having the class name “pier front view”. Further, information indicating that a height of the pier column is 11 m is obtained from the dimensional values and a plane of projection of the internal data of “View”.

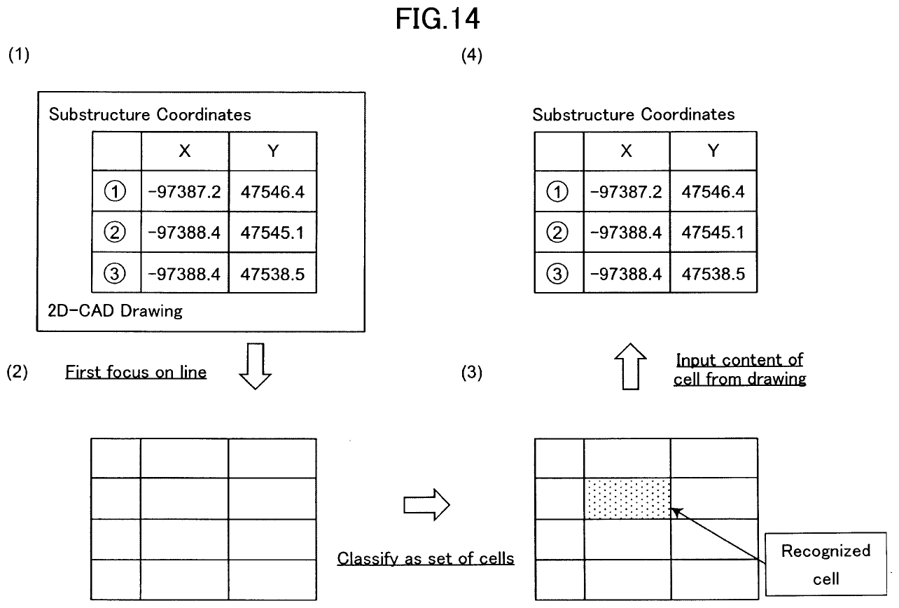

With respect to the various tables, attention is drawn to the lines, as illustrated in FIG. 14(1) and FIG. 14(2). In other words, objectization (class name “LineBuf2D”) is performed with respect to the data, which is a collection of lines. Next, as illustrated in FIG. 14(2) and FIG. 14(3), the object is interpreted as an object having the class name “CellSet”. Next, as illustrated in FIG. 14(3) and FIG. 14(4), the contents of the cell, such as the character string or the like, are input from the drawing, and interpreted as an object having the class name “Table”, and further interpreted as an object having the class name “substructure coordinates”.

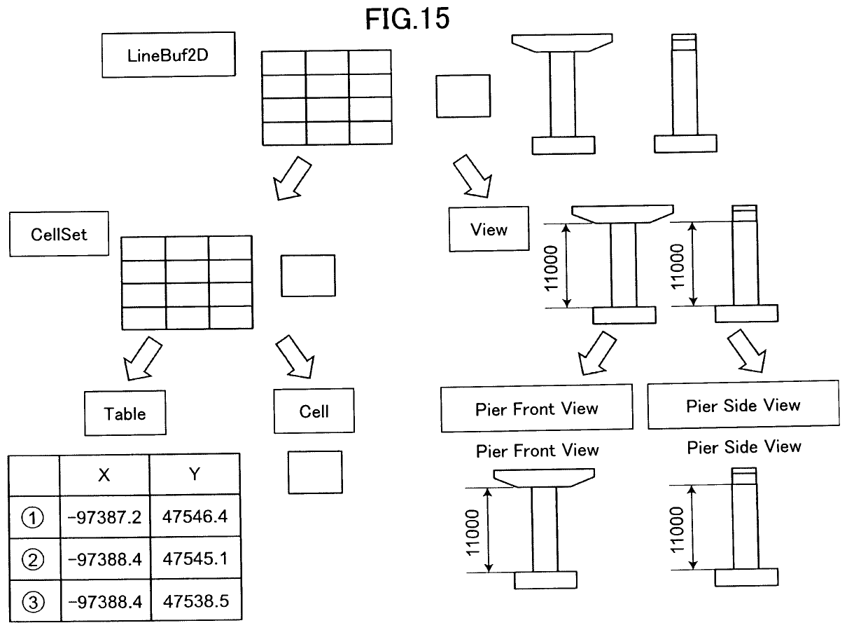

As illustrated in FIG. 15, in the various tables, the object (class name “LineBuf2D”), which is a collection of lines, is interpreted as an object (class name “CellSet”), which is a collection of cells, and further interpreted as an object (class name “Table”) having a plurality of cells filled with the contents or an object (class name “Cell”) including only one cell. Similarly, as illustrated in FIG. 15, with respect to the various drawings, an object (class name “LineBuf2D”), which is a collection of lines, is interpreted as an object (class name “View”), which is a drawing with dimensional values, and further interpreted as an object (class name “Pier Front View”) which has items unique to the “Pier Front View” or an object (class name “Side View”) which has items unique to the “Pier Side View”.

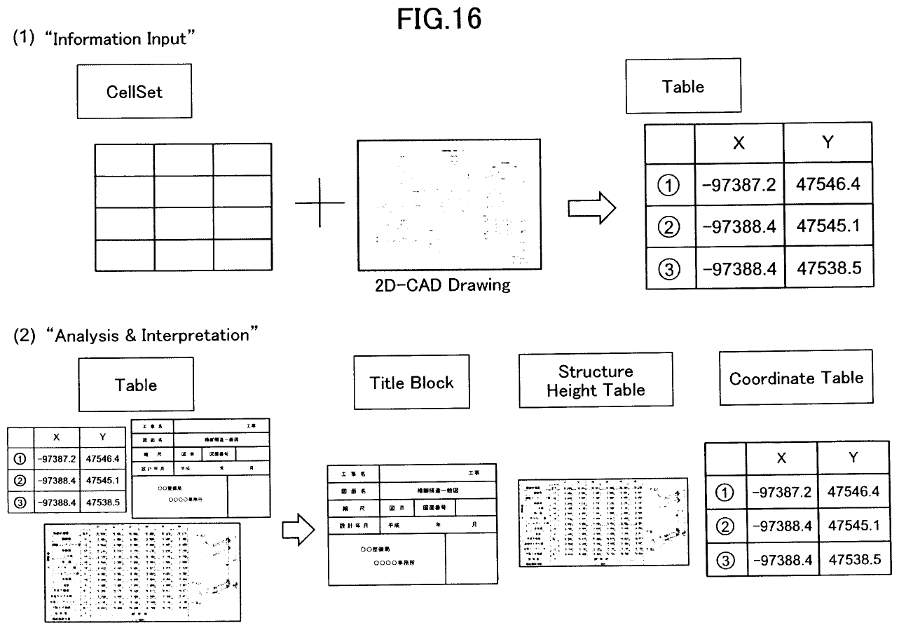

As illustrated in FIG. 16, in the present embodiment, two methods are set as the recognition method of the 2D-CAD drawing. The methods are (1) “Information Input”, and (2) “Analysis & Interpretation”.

As illustrated in FIG. 16(1) as an example, when information on the drawing is input, as additional information from the input data, to an object (class name “CellSet”) which is a set of cells, the object can be interpreted as an object having the class name “Table”.

Further, as illustrated in FIG. 16(2) as an example, by analyzing, classifying, and downcasting the items or the like in the object having the class name “Table”, the object having the class name “title block”, the object having the class name “structure height table”, and the object having the class name “coordinate Table” can be interpreted.

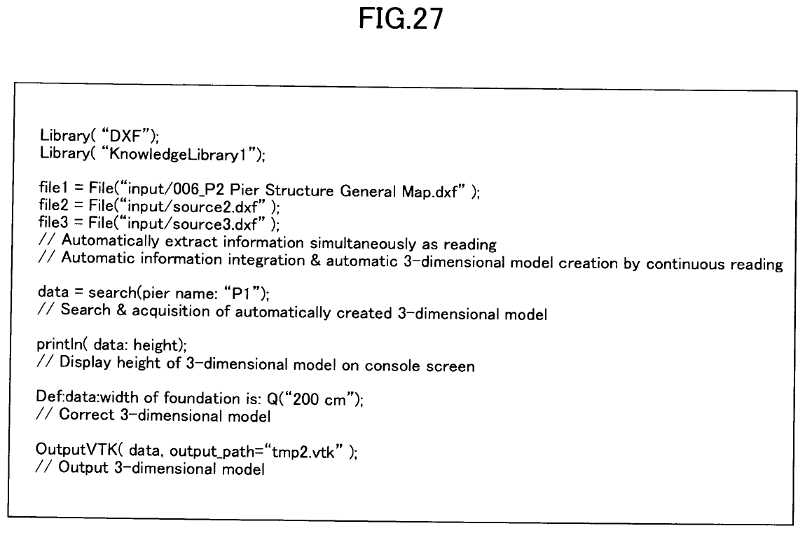

FIG. 27 illustrates an example of a script for interpreting a 2D-CAD drawing “006_P2 pier structure general plan.dxf”. This script is an example of a language understood by the data processing platform according to the present disclosure. Of course, the data processing platform according to the present disclosure may be an other interpreter, other than the interpreter created by the present inventor, as long as the other interpreter satisfies the requirements described above. The script may also be in a language understood by the other interpreter.

### 5. [Second Embodiment]

A data integration apparatus 2′ according to the present embodiment integrates fragmentary information distributed in a plurality of data, to create a model of a data expression target.

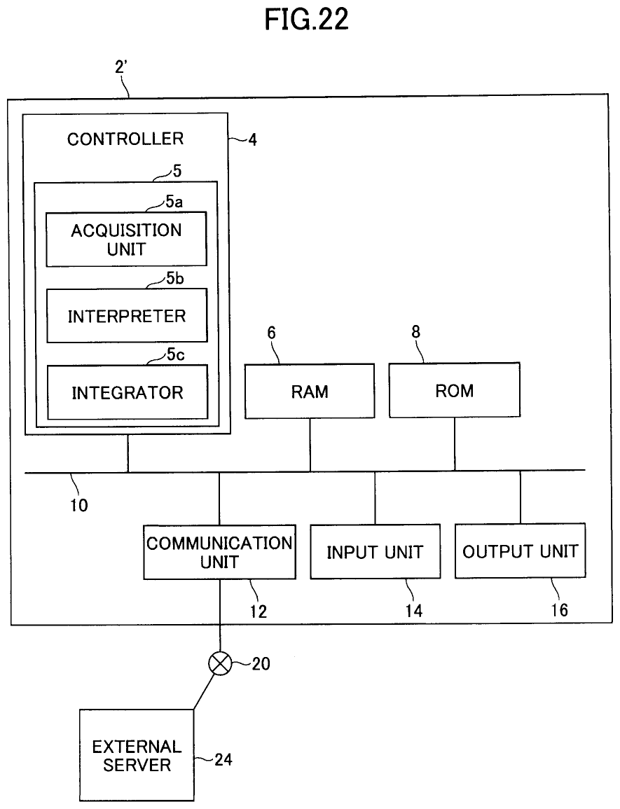

The data integration apparatus according to the second embodiment will be described with reference to FIG. 22.

### 5.1. Configuration of Data Integration Apparatus

FIG. 22 is a diagram illustrating a physical configuration of the data integration apparatus 2′ according to the present embodiment. The data integration apparatus 2′ includes a controller 4 corresponding to a hardware processor, a random access memory (RAM) 6 corresponding to a memory, a read only memory (ROM) 8 corresponding to a memory, a communication unit 12, an input unit 14, and an output unit 16. These components are connected to each other via a bus 10, so that data transmission and reception are possible among these components via the bus 10. The communication unit 12 is a communication interface that connects the data integration apparatus 2′ to an external network 20, and the data integration apparatus 2′ is also connected to an external server 24 via the external network 20 to which the communication unit 12 connects. The RAM 6, the ROM 8, the communication unit 12, the input unit 14, the output unit 16, and the bus 10 are the same as those of the first embodiment illustrated in FIG. 1.

The controller 4 is provided with a platform 5 (a data processing platform in this example). The platform 5 includes functional blocks including an acquisition unit 5a, an interpreter 5b, and an integrator 5c.

The acquisition unit 5a acquires input data, as an object. The input data may be structured data, or may be non-structured data.

The interpreter 5b creates an initial graph with respect to the object acquired by the acquisition unit 5a, and interprets a result of automatically structuring a graph from the initial graph, as an interpretation of the input data. In this interpretation, the interpreter 5b appropriately performs the type conversion of the object associated with each node and each link of the graph, to the hyponymy-side or the hypernymy-side, and varies the structure of the graph representing the relationship of the objects according to the type conversion. Further, a language expression is generated as a result of the interpretation (type conversion and variation of graph structure), and sent to the integrator 5c.

The integrator 5c receives the language expression sent from the interpreter 5b, and holds the language expression as information. In addition, the integrator 5c refines the information based on an inference process. Moreover, the integrator 5c converts the graph according to the language expression, and reflects the information to the graph (integration of information by conversion of the graph). The graph subjected to the conversion process according to the language expression has an aspect of integrated data obtained by integrating the information. The integrated data (a model of the expression target) with respect to the expression target of the input data is generated as this graph (a group of objects forming the graph and an entire structure of the graph). The integrator 5c refines the information according to the inference process, based on the hypernymy-hyponymy relationship of the object corresponding to each word of the language expression. In addition, the integration of the information by the conversion of the graph is performed based on the hypernymy-hyponymy relationship of the object associated with each node and each link of the graph.

By the configuration described above, the data integration apparatus 2′ according to the present embodiment integrates a plurality of fragmentary information extracted from a plurality of data that become the material, to construct desired data.

Further, the data integration apparatus 2′ according to the present embodiment automatically converts the data structure of objects having different expression formats, automatically searches the path of the type conversion, and also automatically constructs the integrated data.

### 5.2. Operation of Data Integration Apparatus

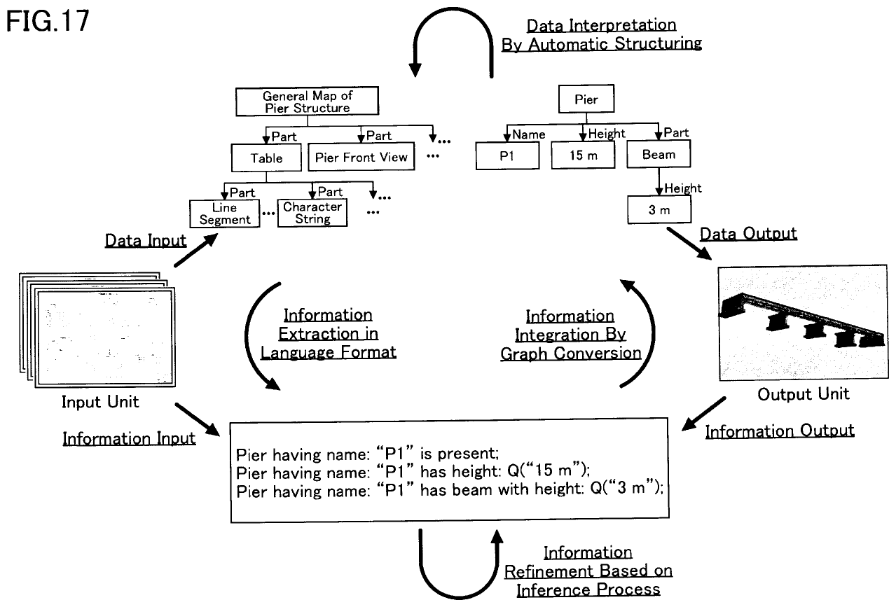

A flow of a digital bridge automatic building method according to the present disclosure is illustrated in FIG. 17. Data (for example, a design drawing or the like) input from the input unit is individually interpreted by automatic interpretation of data by automatic structuring using an automatic type conversion to the hyponymy-side as a starting point, and a plurality information (language expressions) are extracted based on the interpretation result. The extracted information and the information input from the input unit (for example, a user input or the like) are refined by the inference process, as appropriate, and integrated by a conversion of the graph according to the information (language expression), thereby building a digital bridge, such as a three-dimensional bridge model, and outputting the digital bridge from the output unit. The digital bridge automatic building process includes the following three processes. The language expression refers to information expressed in a language format similar to a natural language.
(1) Data interpretation process;
(2) Information extraction process; and
(3) Identification and integration process.

The process (1) corresponds to the data interpretation by the automatic structuring in FIG. 17, the process (2) corresponds to the extraction of information in a language format (language expression) based on the interpretation result, and the process (3) corresponds to integration of information by the conversion of the graph. In addition, the first embodiment is an example including the processes (1) and (2), while the second embodiment includes the processes (1) through (3).

### 5.2.1. (1) Data Interpretation Process

The data interpretation process was described under “4.2.0”.

### 5.2.2. (2) Information Extraction Process

The process extracts information in the language format similar to the natural language, from the graph obtained as the interpretation result of the plurality of input data including the drawing. For example, an actual target expressed by the drawing is identified from the internal data of the object forming the graph and the structure of the graph, and the language expression is collected as a description of the target. For example, the following language expression is extracted as a language expression having a subject for identifying an object, and a predicate representing the properties of the object.
Def: There is a bridge;
Def: The bridge has a pier;
Def: The bridges has a name: “P1”:;
Def: The pier having the name: “P1”: has a height: “Q(13m)”:;

### 5.2.3. (3) Identification and Integration Process

The integration of a plurality of language expressions (information) obtained in the information extraction process is performed by successively performing the conversion of the graph according to the language expression, with respect to one graph. The graph, which is the integrated data obtained as a result of the integration, includes the expression target (for example, “P1 pier” and “A2 pier”) identified from the data as a portion of the graph, and information related to each expression model is also reflected and integrated as a portion of the graph. In this integration process, the automatic structuring of the graph is performed, similar to when the drawing is interpreted.

In the information extraction process, the information is obtained as a collection of language expressions, such as “Def: Height of pier having a name :“P1”: is :Q(“13m”):;”, as described above. In order to integrate the contents of the language expression into one graph, a node of the graph corresponding to the subject of the language expression is identified, and the conversion of the graph corresponding to the predicate is applied, for example. However, some language expressions may describe the presence of a specific node, or may describe a content of the graph to be corrected according to a certain rule, and the conversion of the graph corresponding to each language expression is performed. In this case, if the conversion of the graph corresponding to a certain language expression is not defined, the information thereof may be ignored, and the conversion of the graph may be implemented later.

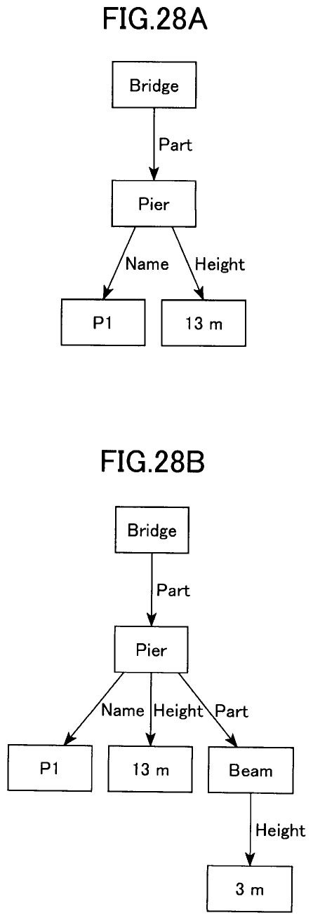

As an example, a result obtained by integrating the contents of each language expression extracted in the information extraction process into one graph, is illustrated in FIG. 28A and FIG. 28B.

FIG. 28A illustrates the result of integrating the following language expressions into one graph.
Def: There is a bridge;
Def: The bridge has a pier;
Def: The bridge has a name: “P1”:;
Def: The pier having the name: “P1”: has a height: “Q(13m)”:;

In addition, FIG. 28B illustrates the result of integrating the following language expressions into one graph.
Def: There is a bridge;
Def: The bridge has a pier;
Def: The bridge has a name: “P1”:;
Def: The pier having the name: “P1”: has a height: “Q(13m)”:;
Def: The bridge has a beam;
Def: The beam has a height: “Q(3m)”:;

In this case, the relationship of the nodes (for example, “portion”, “name”, “height”, or the like) is expressed in the link portion of the graph.

It is not necessary that all of the language expressions integrated by the conversion of the graph are extracted in the information extraction process, and the language expression may be input or the like from the user, another program, or the like. For example, among the language expressions for obtaining the graph illustrated in FIG. 28B, the language expression “Def: Height of beam is “:Q(3m)”:;” may be input by the user. In addition, the content of the language expression may represent engineering knowledge or any inference or estimation based on the engineering knowledge.

The graph in which the contents of each language expression are integrated is obtained by successively performing the conversion of the graph according to the language expression.

For example, it is assumed that the following language expressions (1) through (4) are successively obtained.
(1) Def: There is a bridge;
(2) Def: The bridge has a pier;
(3) Def: The bridge has a name: “P1”:
(4) Def: The bridge having a name: “P2”: is located on the bridge;

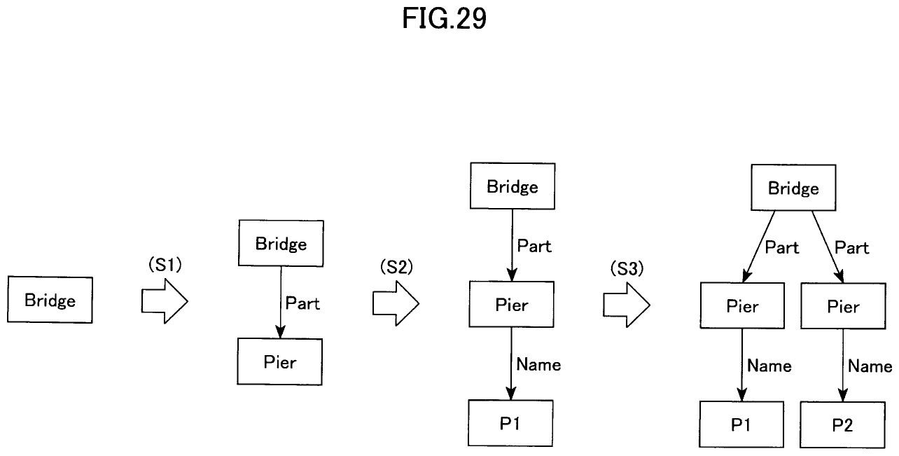

In this state, as illustrated in FIG. 29, when the language expression indicated in (2) is obtained after the language expression indicated in (1) is obtained, the graph is converted as indicated by S1. Next, when the language expression indicated in (3) is obtained, the graph is converted as indicated by S2. Then, when the language expression indicated in (4) is obtained, the graph is converted as indicated by S3. The automatic structuring of the graph is performed every time the graph is converted, and the object of an expression target (bridge, pier, or the like) of the drawing associated with the node of the graph is automatically converted into the object on the hyponymy-side including detailed internal data. When automatically structuring the graph, engineering knowledge or any inference or estimation technology, for example, is used, as required. For example, even if a relationship between an object and another object is not obtained from information extracted from a drawing, but is obtained by the engineering knowledge or any inference or estimation technology, the relationship can be used to perform the automatic structuring of the graph.

By using the graph that is obtained in this manner, it is possible to output a three-dimensional model of the structure represented by the graph. As described above, not only information extracted from the drawing, but also a language expression input from the user, another program, or the like can be used as the language expression, and for this reason, it is possible to create a three-dimensional model in which some elements of the CAD drawing are modified or the like, for example. Hence, it is possible to obtain a three-dimensional model of an arbitrary structure by modifying some elements of a CAD drawing of an existing structure, for example.

### 5.2.4.2 Application to Two-Dimensional CAD Drawing

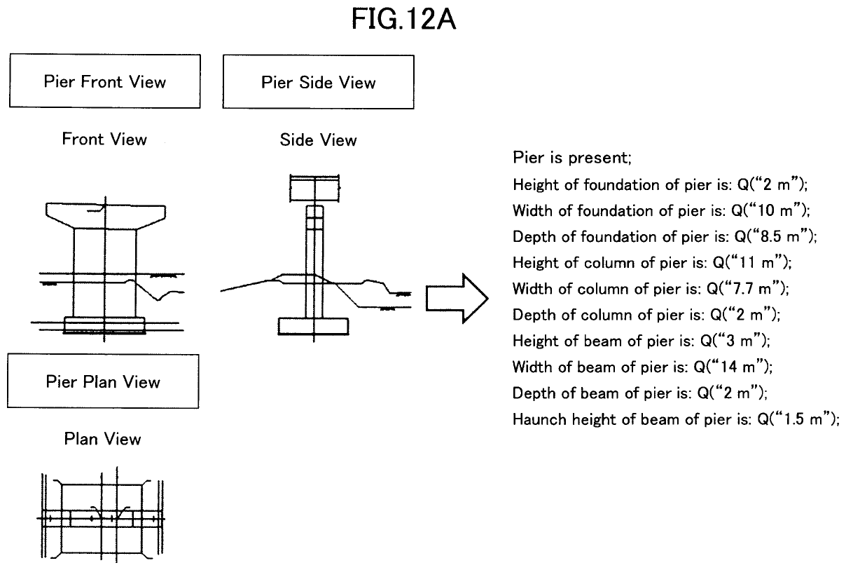

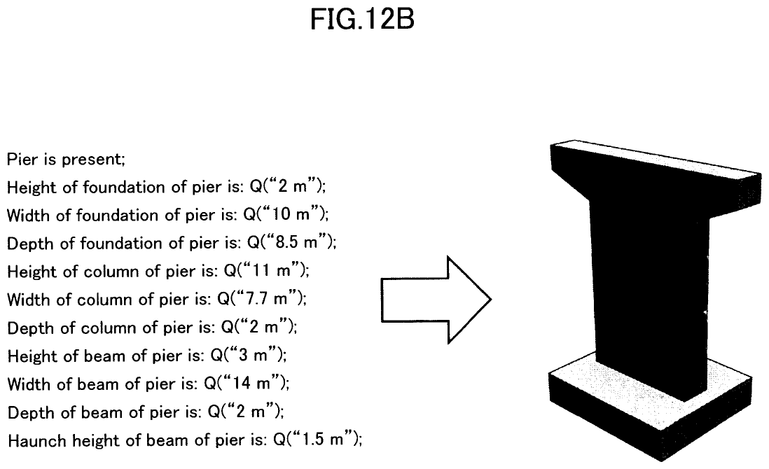

In order to examine the digital bridge automatic building method according to the present disclosure, an attempt was made to automatically interpret and automatically build an expression target, with respect to a drawing of a two-dimensional CAD (DXF format) in which elements of the drawing, such as line segments, character strings, or the like, are recorded in a vector format. FIG. 20 illustrates an example where a three-dimensional model of a pier is automatically built by the attempt. As a result of the interpretation of the drawing, “pier front view”, “pier plan view” and “pier side view” are interpreted. Information on the structure is automatically extracted from the “pier front view”, the “pier plan view”, and the “pier side view”, and a three-dimensional model is automatically created from the information on the structure. FIG. 12A is a diagram illustrating a state where the information on the structure is automatically extracted from the front view, the plan view, and the side view, and FIG. 12B is a diagram illustrating a state where a three-dimensional model is automatically created from the information on the structure.

### 6. Other Embodiments

The first and second embodiments are described above as examples of the technology disclosed in the present application. However, the technology of the present disclosure is not limited to these embodiments, and can be applied to embodiments in which a modification, a substitution, an addition, an omission, or the like is appropriately made.

In addition, the accompanying drawings and detailed description have been provided to explain the embodiments. Accordingly, the constituent elements described in the accompanying drawings and the detailed description may include not only constituent elements essential for solving the problem but also constituent elements which are not essential for solving the problem in order to exemplify the technology. For this reason, these non-essential constituent elements described in the accompanying drawings and the detailed description should not be construed as essential constituent elements.

Further, because the embodiments described above are intended to exemplify the technology of the present disclosure, various modifications, substitutions, additions, omissions, or the like can be made within the scope of the claims and the scope equivalent thereto.

This application is based on and Japanese Patent Application No. 2021-016118, filed on Feb. 3, 2021, the entire contents of which are incorporated herein by reference.

### DESCRIPTION OF REFERENCE NUMERALS

2: data interpretation apparatus, 2′: data integration apparatus, 4: controller, 5: platform, 5a: acquisition unit, 5b: interpreter, 5c: integrator, 6: RAM, 8: ROM, 10: bus, 12: communication unit, 14: input unit, 16: output unit, 20: external network, 24: external server

1. A data integration apparatus comprising:
a controller; and
a platform configured to automatically perform a type conversion of objects, wherein
the platform is provided in the controller, and includes an interpreter and an integrator, and
the controller is operated so that
the interpreter generates information of a language format in which objects are associated with words, from a graph representing a relationship of the objects of the platform, and
the integrator holds the information, and performs creation and conversion of the graph so as to reflect the information on the graph.

2. The data integration apparatus as claimed in claim 1, wherein the integrator
reflects on the graph, in addition to the information generated by the interpreter, information of the language format input by a user, so as to integrate the information generated by the interpreter and the information of the language format input by the user.

3. The data integration apparatus as claimed in claim 1, wherein the interpreter
converts a structure of the graph representing the relationship of the objects of the platform, based on a hypernymy-hyponymy relationship of the objects, so that constituent elements of the graph are converted into a type more on the hyponymy-side.

4. The data integration apparatus as claimed in claim 1, wherein the integrator
performs an inference process with respect to the information of the language format held by the integrator, by taking into consideration a hypernymy-hyponymy relationship of the objects, so as to convert the information held by the integrator.

5. The data integration apparatus as claimed in claim 1, wherein the information of the language format is similar to a natural language, and the controller
generates an output to a user, according to the natural language or a word or sentence similar to the natural language input by the user.

6. A data integration method using a platform configured to automatically performing a type conversion of objects, wherein
the platform is provided in a controller of a computer, and includes an interpreter and an integrator, and
performs a process comprising:
generating, by the interpreter, information of a language format in which objects are associated with words, from a graph representing a relationship of the objects of the platform; and
holding, by the integrator, the information, to perform creation and conversion of the graph so as to reflect the information on the graph.

7. A non-transitory computer-readable storage medium having stored therein a program to be executed by a computer, wherein
a platform is provided in a controller of the computer, and includes an interpreter and an integrator, and automatically performs a type conversion of objects, and
the program which, when executed by the computer, causes the controller of the computer to perform a process including:
generating, by the interpreter, information of a language format in which objects are associated with words, from a graph representing a relationship of the objects of the platform; and
holding, by the integrator, the information, to perform creation and conversion of the graph so as to reflect the information on the graph.

8. A digital city building system comprising a platform for automatically performing a type conversion of objects, and element programs, wherein
the platform implements a loose coupling of the element programs by abstracting an input format of the element programs and extending an application range, by path search and automatic execution of a type conversion based on a hypernymy-hyponymy relationship of the objects.

9. The digital city building system as claimed in claim 8, wherein
the platform is provided in a controller of the system, and includes an interpreter and an integrator, and
the controller is operated so that
the interpreter generates information of a language format in which objects are associated with words, from a graph representing a relationship of the objects of the platform; and
the integrator holds the information, and performs creation and conversion of the graph so as to reflect the information on the graph.

10. The digital city building system as claimed in claim 8, wherein an expression target of the data integrated by the interpreter and the integrator of the platform is a city or a structure.
